(19) United States
(12) Patent Application Publication
(10) Pub. No.: US 2025/0358943 A1
(43) Pub. Date: Nov. 20, 2025

(54) ELECTRONIC DEVICE INCLUDING ROLLABLE DISPLAY

(71) Applicant: Samsung Electronics Co., Ltd., Suwon-si (KR)

(72) Inventors: Changha YU, Suwon-si (KR); Ohheon KWON, Suwon-si (KR); Gyubok PARK, Suwon-si (KR); Mincheol SEO, Suwon-si (KR); Sangmok LEE, Suwon-si (KR); Uichul JEONG, Suwon-si (KR); Jaebong CHUN, Suwon-si (KR)

(21) Appl. No.: 19/240,808

(22) Filed: Jun. 17, 2025

Related U.S. Application Data
(63) Continuation of application No. PCT/KR2025/006526, filed on May 14, 2025.

(30) Foreign Application Priority Data
May 14, 2024 (KR) 10-2024-0063444
Aug. 20, 2024 (KR) 10-2024-0111228

(51) Int. Cl. H05K 5/02

(52) U.S. Cl. CPC H05K 5/0217

(57) ABSTRACT

An electronic device is provided. The electronic device includes a housing including a first housing part and a second housing part movably joined with the first housing part between a retracted position and an extended position with respect to the first housing part, a flexible display joined with the first housing part and the second housing part so that a region viewed to a front side of the housing changes in size with movement of the second housing part between the retracted position and the extended position, an actuator configured to move the second housing part with respect to the first housing part, and a conductive coupling member disposed at one end of the flexible display and extending in a direction facing the second housing part. The flexible display may be rolled inside the second housing part toward a rear side of the second housing part. The one end of the flexible display may move in a lengthwise direction of the second housing part in vicinity of the rear side of the second housing part with the movement of the second housing part between the retracted position and the extended position with respect to the first housing part. When the second housing part moves from the retracted position to the extended position with respect to the first housing part, the conductive coupling member may be electrically coupled to the second housing part so that the flexible display is grounded to the second housing part.

### CROSS-REFERENCE TO RELATED APPLICATION(S)

This application is a continuation application, claiming priority under 35 U.S.C. § 365(c), of an International application No. PCT/KR2025/006526, filed on May 14, 2025, which is based on and claims the benefit of a Korean patent application number 10-2024-0063444, filed on May 14, 2024, in the Korean Intellectual Property Office, and of a Korean patent application number 10-2024-0111228, filed on Aug. 20, 2024, in the Korean Intellectual Property Office, the disclosure of each of which is incorporated by reference herein in its entirety.

### TECHNICAL FIELD

The disclosure relates to an electronic device including a rollable display.

### BACKGROUND ART

With the advance of display technologies, research and development on electronic devices having flexible displays is actively underway. For example, there is ongoing research and development on a form factor which allows the display to be folded, bent, rolled, or unfolded, by applying a rollable display to the electronic device.

The electronic device may be designed to have a rollable display rolled inside a hollow housing. The electronic device may be designed such that the rollable display is drawn out to the outside from the inside of the hollow housing, based on a specified event.

The above information is presented as background information only to assist with an understanding of the disclosure. No determination has been made, and no assertion is made, as to whether any of the above might be applicable as prior art with regard to the disclosure.

### DISCLOSURE

### Technical Solution

Aspects of the disclosure are to address at least the above-mentioned problems and/or disadvantages and to provide at least the advantages described below. Accordingly, an aspect of the disclosure is to provide an electronic device including a rollable display.

Additional aspects will be set forth in part in the description which follows and, in part, will be apparent from the description, or may be learned by practice of the presented embodiments.

In accordance with an aspect of the disclosure, an electronic device is provided. The electronic device includes a housing including a first housing part and a second housing part movably joined with the first housing part between a retracted position and an extended position with respect to the first housing part, a flexible display joined with the first housing part and the second housing part so that a region viewed to a front side of the housing changes in size with movement of the second housing part between the retracted position and the extended position, an actuator configured to move the second housing part with respect to the first housing part, and a conductive coupling member disposed at one end of the flexible display and extending in a direction facing the second housing part. The flexible display may be rolled inside the second housing part toward a rear side of the second housing part. The one end of the flexible display may move in a lengthwise direction of the second housing part in vicinity of the rear side of the second housing part with the movement of the second housing part between the retracted position and the extended position with respect to the first housing part. When the second housing part moves from the retracted position to the extended position with respect to the first housing part, the conductive coupling member may be electrically coupled to the second housing part so that the flexible display is grounded to the second housing part.

Other aspects, advantages, and salient features of the disclosure will become apparent to those skilled in the art from the following detailed description, which, taken in conjunction with the annexed drawings, discloses various embodiments of the disclosure.

### DESCRIPTION OF DRAWINGS

The above and other aspects, features, and advantages of certain embodiments of the disclosure will be more apparent from the following description taken in conjunction with the accompanying drawings

FIG. 1 is a block diagram illustrating an electronic device in a network environment according to an embodiment of the disclosure;

FIG. 2A is a top plan view of an electronic device in a first state according to an embodiment of the disclosure;

FIG. 2B is a bottom view of an electronic device in a first state according to an embodiment of the disclosure;

FIG. 2C is a top plan view of an electronic device in a second state according to an embodiment of the disclosure;

FIG. 2D is a bottom view of an electronic device in a second state according to an embodiment of the disclosure;

FIG. 3A is an exploded perspective view of an electronic device according to an embodiment of the disclosure;

FIG. 3B is an exploded perspective view of an electronic device according to an embodiment of the disclosure;

FIG. 4A is a cross-sectional view of an electronic device in a first state according to an embodiment of the disclosure;

FIG. 4B is a cross-sectional view of an electronic device in a second state according to an embodiment of the disclosure;

FIG. 5 is a drawing for explaining an antenna disposed to an electronic device according to an embodiment of the disclosure;

FIG. 6 is a drawing for explaining antenna performance depending on a state change of an electronic device from a first state to a second state according to an embodiment of the disclosure;

FIG. 7 is a drawing for comparative description of antenna performance when an electronic device is in a first state and antenna performance when the electronic device is in a second state according to an embodiment of the disclosure;

FIG. 8A is a drawing for explaining performance of an antenna of which an element is coupled, when an electronic device is in a first state according to an embodiment of the disclosure;

FIG. 8B is a drawing for explaining performance of an antenna of which an element is coupled, when an electronic device is in a second state according to an embodiment of the disclosure;

FIG. 9 is a drawing for comparative description of antenna performance when an electronic device is in a first state and antenna performance when the electronic device is in a second state according to an embodiment of the disclosure;

FIG. 10 is a drawing for explaining a cross-section of an electronic device according to an embodiment of the disclosure;

FIG. 11 is a drawing for explaining a conductive coupling member of an electronic device according to an embodiment of the disclosure;

FIG. 12 is a drawing for comparative description of antenna performance depending on whether an electronic device has a conductive coupling member according to an embodiment of the disclosure;

FIG. 13 is a drawing for explaining a conductive coupling member of an electronic device according to an embodiment of the disclosure;

FIG. 14 is a drawing for explaining a conductive coupling member of an electronic device according to an embodiment of the disclosure;

FIG. 15 is a drawing for explaining a conductive coupling member of an electronic device according to an embodiment of the disclosure;

FIG. 16 is a drawing for explaining a second housing part with which a conductive coupling member of an electronic device is in contact according to an embodiment of the disclosure;

FIG. 17 is a drawing for explaining a second housing part with which a conductive coupling member of an electronic device is in contact according to an embodiment of the disclosure;

FIG. 18 is a drawing for explaining a second housing part with which a conductive coupling member of an electronic device is in contact according to an embodiment of the disclosure;

FIG. 19 is a drawing for explaining performance of an antenna when a conductive coupling member of an electronic device in a second state is not in contact with a second housing part according to an embodiment of the disclosure;

FIG. 20 is a drawing for explaining performance of an antenna when a conductive coupling member of an electronic device in a second state is in contact with a second housing part according to an embodiment of the disclosure;

FIG. 21 is a drawing for explaining a second housing part with which a conductive coupling member of an electronic device is selectively in contact according to an embodiment of the disclosure;

FIG. 22 is a drawing for explaining a second housing part with which a conductive coupling member of an electronic device is in contact according to an embodiment of the disclosure;

FIG. 23 is a drawing for explaining antenna performance depending on a position at which a conductive coupling member of an electronic device is in contact according to an embodiment of the disclosure;

FIG. 24 is a drawing for explaining antenna performance depending on a position at which a conductive coupling member of an electronic device is in contact according to an embodiment of the disclosure;

FIG. 25 is a drawing for explaining antenna performance depending on a position at which a conductive coupling member of an electronic device is in contact according to an embodiment of the disclosure;

FIG. 26 is a drawing for explaining antenna performance depending on a position at which a conductive coupling member of an electronic device is in contact according to an embodiment of the disclosure;

FIG. 27 is a drawing for explaining antenna performance depending on a position at which a conductive coupling member of an electronic device is in contact according to an embodiment of the disclosure;

FIG. 28 is a drawing for explaining antenna performance depending on a position at which a conductive coupling member of an electronic device is in contact according to an embodiment of the disclosure;

FIG. 29 is a drawing for explaining antenna performance depending on a position at which a conductive coupling member of an electronic device is in contact according to an embodiment of the disclosure; and

FIG. 30 is a drawing for explaining antenna performance depending on a position at which a conductive coupling member of an electronic device is in contact according to an embodiment of the disclosure.

Throughout the drawings, it should be noted that like reference numbers are used to depict the same or similar elements, features, and structures.

### MODE FOR INVENTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

An electronic device including a rollable display may provide a wide size to a user in a state where the rollable display is unrolled, and may provide portability to the user in a state where the rollable display is rolled. The rollable display drawn into a housing of the electronic device may cause a complicated inner structure of the electronic device and an insufficient space for mounting parts. In addition, the rollable display drawn into the housing of the electronic device may cause deterioration of antenna performance. For example, the electronic device may experience the deterioration of antenna performance due to capacitance produced between the rollable display and the housing.

According to the disclosed embodiments, the electronic device may provide constant antenna performance regardless of whether the rollable display is drawn into the housing or drawn out from the housing.

Advantages acquired in the disclosure are not limited to the aforementioned advantages, and other advantages not mentioned herein may be clearly understood by those skilled in the art to which the disclosure pertains from the following descriptions.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi™) chip, a Bluetooth™ chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

Hereinafter, with reference to the attached drawings, embodiments are described in detail so as to be readily implemented by those skilled in the art to which the disclosure pertains. However, the disclosed embodiments can be realized in different forms and are not limited to the embodiments described herein.

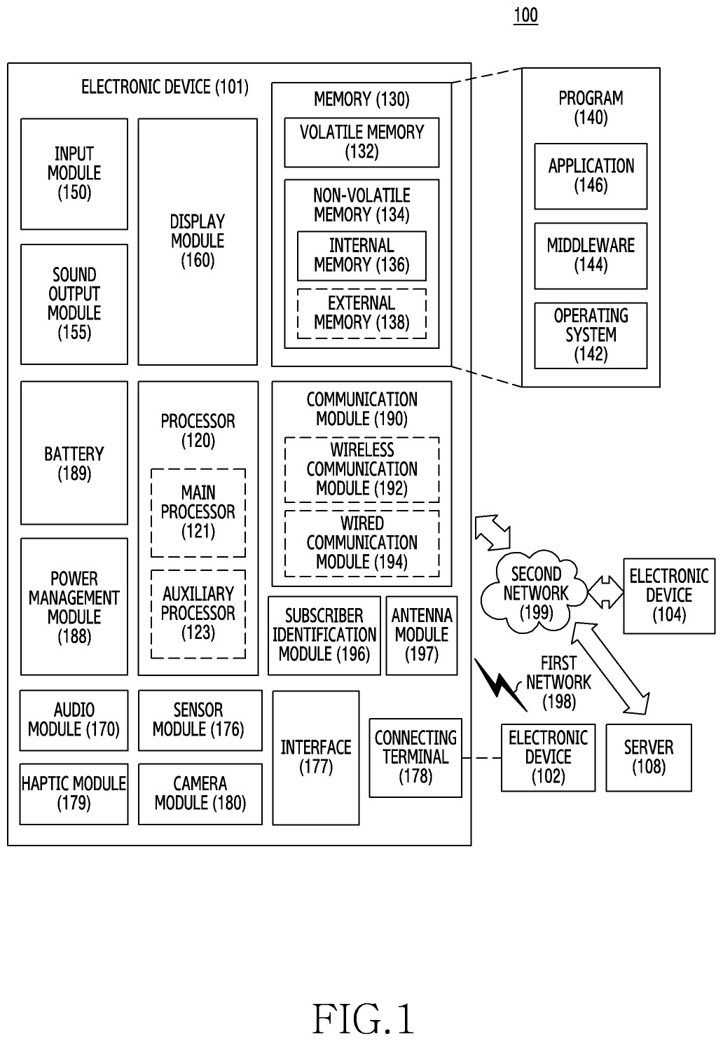

FIG. 1 is a block diagram illustrating an electronic device in a network environment according to an embodiment of the disclosure.

Referring to FIG. 1, an electronic device 101 in a network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a haptic module 179, a camera module 180, a power management module 188, a battery 189, a communication module 190, a subscriber identification module (SIM) 196, or an antenna module 197. In some embodiments, at least one (e.g., the display module 160 or the camera module 180) of the components may be omitted from the electronic device 101, or one or more other components may be added in the electronic device 101. In some embodiments, some of the components may be implemented as single integrated circuitry. For example, the sensor module 176 (e.g., a fingerprint sensor, an iris sensor, or an illuminance sensor) may be implemented as embedded in the display module 160 (e.g., a display).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may load a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), and an auxiliary processor 123 (e.g., a graphics processing unit (GPU), an image signal processor (ISP), a sensor hub processor, or a communication processor (CP)) that is operable independently from, or in conjunction with, the main processor 121. Additionally or alternatively, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134. The non-volatile memory 134 may include internal memory 136 and external memory 138.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record, and the receiver may be used for an incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include touch circuitry adapted to detect a touch, or sensor circuitry (e.g., a pressure sensor) adapted to measure the intensity of force incurred by the touch.

According to one embodiment, the display module 160 may be flexible. For example, the display module 160 may form at least part of the outer surface of the electronic device 101 and may include a display area that is visually exposed outside the housing of the electronic device 101. For example, since the display module 160 has flexibility, at least a portion of the display module 160 may be rollable into or slidable into the housing. For example, the size of the display area may vary depending on the size of at least the portion of the display module 160 that is rolled or slid into the housing.

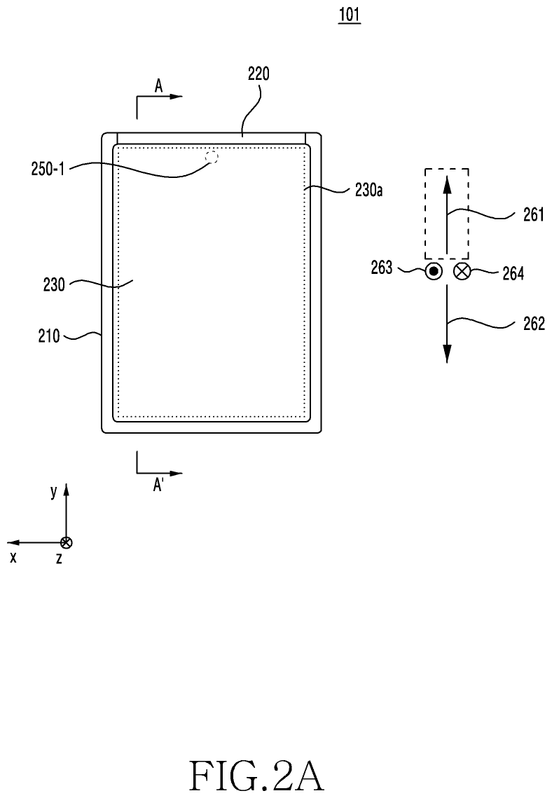

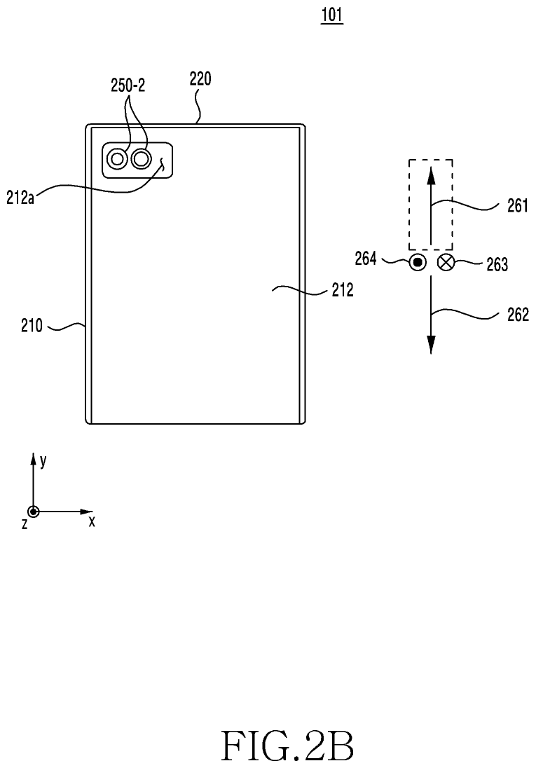

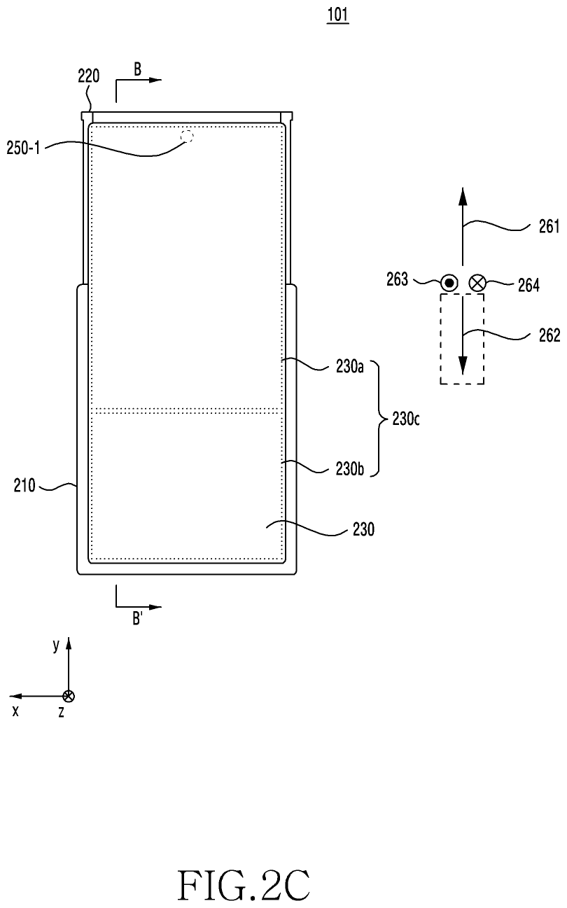

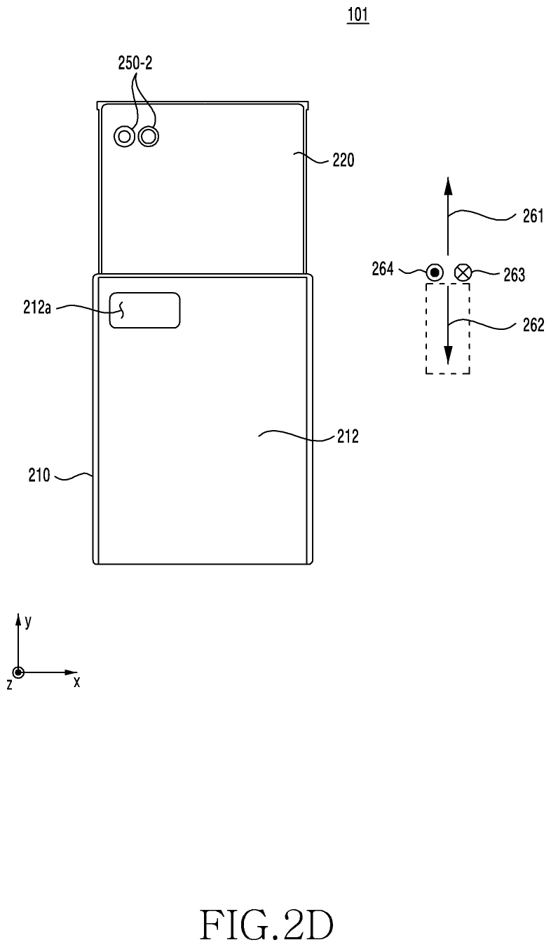

According to one embodiment, the electronic device 101 including the display module 160 may be in one of multiple states, including a first state in which the display area has a first size and a second state in which the display area has a second size different from the first size. For example, the first state may correspond to the state of the electronic device 101 described with reference to FIGS. 2A and 2B, and the second state may correspond to the state described with reference to FIGS. 2C and 2D.

According to one embodiment, the first state may transition to the second state. For example, the first state (or the second state) may transition to the second state (or the first state) through one or more intermediate states between the first and second states. The transition from the first state (or the second state) to the second state (or the first state) may be based on a defined user input. For example, the first state (or the second state) may transition in response to user input to a physical button visually exposed through a portion of a first housing (e.g., 210 of FIGS. 2A-2D) or a portion of a second housing (e.g., 220 of FIGS. 2A-2D). There is no limitation on the type of user input. For example, the user input may include input through a touch screen within the display area of the display module 160 or input through a microphone of the electronic device 101. For example, the state of the electronic device 101 may change to the second state (or the first state) by an external force applied to the first housing (e.g., 210 of FIGS. 2A-2D) and/or the second housing (e.g., 220 of FIGS. 2A-2D).

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™ wireless-fidelity (Wi-Fi™) direct, or infrared data association (IrDA)) or the second network 199 (e.g., a long-range communication network, such as a cellular network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., printed circuit board (PCB)). According to an embodiment, the antenna module 197 may include a plurality of antennas. In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 and 104 may be a device of a same type as, or a different type, from the electronic device 101. According to an embodiment, all or some of operations to be executed at the electronic device 101 may be executed at one or more of the external electronic devices (e.g., the electronic devices 102 and 104 and the server 108). For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, or client-server computing technology may be used, for example.

FIG. 2A is a top plan view of an electronic device in a first state according to an embodiment of the disclosure.

Referring to FIG. 2A, an electronic device 101 may include a first housing 210, a second housing 220 movable with respect to the first housing 210 in a first direction 261 parallel with a y-axis or a second direction 262 parallel with the y-axis and opposite the first direction 261, and a display 230 (e.g., the display module 160 of FIG. 1). Although it is described that the second housing 220 moves with respect to the first housing 210, the disclosure is not limited thereto. For example, the first housing 210 may move with respect to the second housing 220. For example, a display region of the display 230 exposed visually to the outside of the housing of the electronic device 101 may change in size, depending on a change in a relative locational relationship between the first housing 210 and the second housing 220.

For example, in the first state, the second housing 220 may be movable with respect to the first housing 210 in the first direction 261 out of the first direction 261 and the second direction 262. For example, in the first state, the second housing 220 may not be movable in the second direction 262 with respect to the first housing 210.

For example, in the first state, the display 230 may provide a display region having a smallest size. For example, in the first state, the display region may correspond to a first region 230a. For example, although not shown in FIG. 2A, in the first state, a region (e.g., a second region 230b of FIG. 2C) of the display 230, different from the display region, i.e., the first region 230a, may be disposed in the first housing 210. For example, in the first state, the second region 230b may be covered by the first housing 210. For example, in the first state, the second region 230b may move into the first housing 210. For example, at least a portion of the second region 230b may be rolled into the first housing 210. For example, in the first state, the first region 230a may include a planner portion. For example, in the first state, a portion of the second region 230b may include a curved portion. However, the disclosure is not limited thereto. For example, the first region 230a may include a curved portion extending from the planar portion, in the first state.

For example, the first state may be referred to as a slide-in state in a sense that at least a portion of the second housing 220 is located inside the first housing 210, in accordance with the second housing 220 which is slid toward the first housing 210. For example, the first state may be referred to as a reduced state in a sense that the display region having the smallest size is provided. However, the disclosure is not limited thereto.

For example, the second housing 220 may include a front camera 250-1 which acquires visual information through a portion of the first region 230a and faces a third direction 263 parallel with a z-axis. For example, although not shown in FIG. 2A, the second housing 220 may include one or more rear cameras (e.g., rear cameras 250-2 of FIG. 2B) exposed visually through a portion of the second housing 220 and facing a fourth direction 264 parallel with the z-axis and opposite the third direction 263. For example, the one or more rear cameras 250-2 may be exemplified with reference to FIG. 2B.

FIG. 2B is a bottom view of an electronic device in a first state according to an embodiment of the disclosure.

Referring to FIG. 2B, in the first state, one or more rear cameras 250-2 disposed in a second housing 220 may be located within a structure disposed in a first housing 210 for the one or more rear cameras 250-2. For example, since the one or more rear cameras 250-2 are located within the structure in the first state, the one or more rear cameras 250-2 may be exposed visually through the structure in the first state. The one or more rear cameras 250-2 may acquire visual information through the structure. For example, the structure may be implemented variously. For example, the structure may be an opening or a notch. For example, the structure may be an opening 212a in a first plate 212 of the first housing 210 surrounding at least a portion of the second housing 220. However, the disclosure is not limited thereto.

FIG. 2C is a top plan view of an electronic device in a second state according to an embodiment of the disclosure.

Referring to FIG. 2C, in the second state, a second housing 220 may be movable with respect to a first housing 210 in a second direction 262 out of a first direction 261 and the second direction 262. For example, in the second state, the second housing 220 may not be movable in the first direction 261 with respect to the first housing 210.

For example, in the second state, the display 230 may provide a display region having a greatest size. For example, in the second state, the display region may correspond to a region 230c including the first region 230a and the second region 230b. For example, the second region 230b included in the first housing 210 in the first state may be exposed visually in the second state. For example, in the second state, the first region 230a and the second region 230b may include a planar portion. However, the disclosure is not limited thereto. For example, the first region 230a and/or the second region 230b may include a curved portion extending from the planar portion and located in an edge portion.

For example, the second state may be referred to as a slide-out state in a sense that at least a portion of the second housing 220 is located outside the first housing 210, in accordance with the second housing 220 which is slid from the first housing 210. For example, the second state may be referred to as an extended state in a sense that the display region having the greatest size is provided. However, the disclosure is not limited thereto.

For example, when the state of the electronic device 101 changes from the first state to the second state, the front camera 250-1 facing the third direction 263 may move together with the first region 230a in accordance with the movement of the second housing 220 in the first direction 261. For example, although not shown in FIG. 2C, when the state of the electronic device 101 changes from the first state to the second state, one or more rear cameras (e.g., the rear cameras 250-2 of FIG. 2D) facing the fourth direction 264 may move together with the second housing 220 in accordance with the movement of the second housing 220 in the first direction 261. For example, a relative locational relationship between the one or more rear cameras 250-2 and the structure exemplified with reference to FIG. 2B may change in accordance with the movement of the one or more rear cameras 250-2. For example, the change in the relative locational relationship may be exemplified with reference to FIG. 2D.

FIG. 2D is a bottom view of an electronic device in a second state according to an embodiment of the disclosure.

Referring to FIG. 2D, in the second state, one or more rear cameras 250-2 may be located outside the structure. For example, in the second state, the one or more rear cameras 250-2 may be located outside an opening 212a in a first plate 212. For example, since the one or more rear cameras 250-2 are located outside the opening 212a in the second state, the one or more rear cameras 250-2 may be exposed visually in the second state. The one or more rear cameras 250-2 located outside the structure may obtain visual information. For example, since the one or more rear cameras 250-2 are located outside the structure in the second state, the relative locational relationship between the structure (e.g., the opening 212a) and the one or more rear cameras 250-2 in the second state may be different from the relative locational relationship between the structure (e.g., the opening 212a) and the one or more rear cameras 250-2 in the first state (e.g., FIG. 2B).

Although not shown in FIGS. 2A, 2B, 2C, and 2D, the electronic device 101 may be in an intermediary state between the first state and the second state. For example, a size of the display region in the intermediary state may be greater than the size of the display region in the first state and smaller than the size of the display region in the second state. For example, the display region in the intermediary state may correspond to a region including a portion of the first region 230a and second region 230b. For example, in the intermediary state, a portion of the second region 230b may be exposed visually, and another portion (or the remaining portion) of the second region 230b may be covered by the first housing 210 or move into the first housing 210. However, the disclosure is not limited thereto.

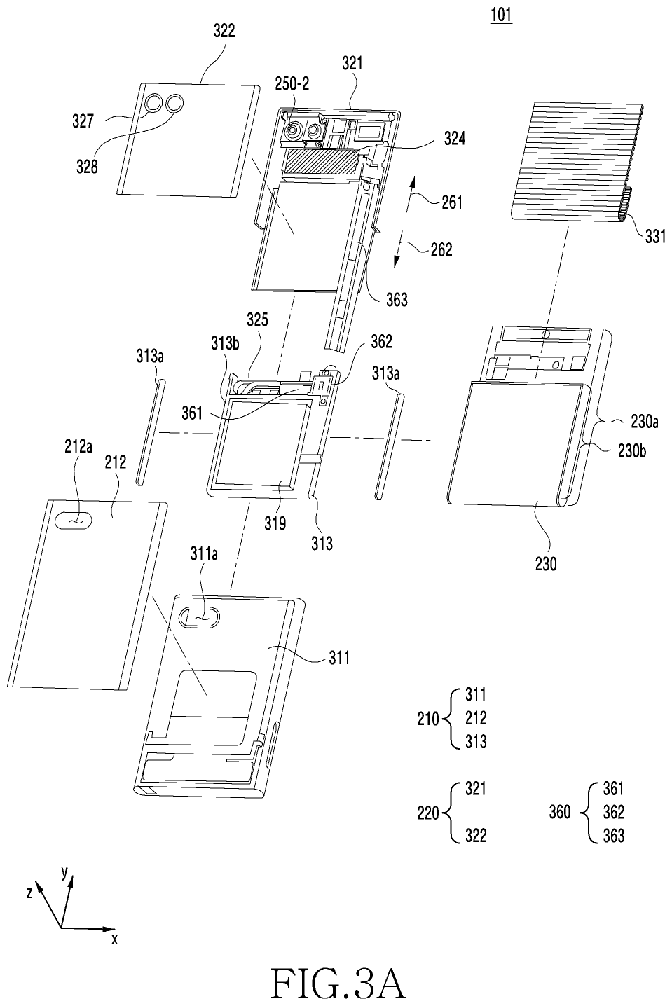

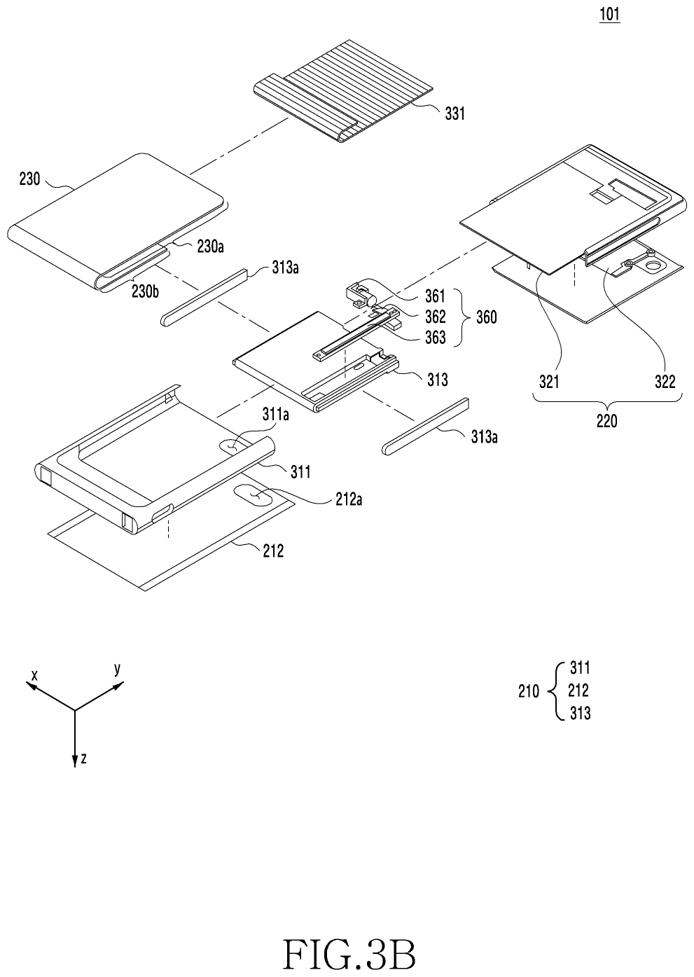

The electronic device 101 may include structures for moving a second housing (e.g., the second housing 220 of FIGS. 2A, 2B, 2C, and 2D) of the electronic device 101 with respect to a first housing (e.g., the first housing 210 of FIGS. 2A, 2B, 2C, and 2D) of the electronic device 101. For example, the structures may be exemplified with reference to FIGS. 3A and 3B.

FIGS. 3A and 3B are exploded perspective views of an electronic device according to various embodiments of the disclosure.

Referring to FIGS. 3A and 3B, an electronic device 101 may include a first housing 210, a second housing 220, a display 230, and a driving unit 360.

For example, the first housing 210 may include a first cover 311, a first plate 212, and a frame 313.

For example, the first cover 311 may at least partially constitute a side portion of an outer face of the electronic device 101. For example, the first cover 311 may at least partially constitute a rear portion of the outer face. For example, the first cover 311 may include an opening 311a for one or more rear cameras 250-2. For example, the first cover 311 may include a face supporting the first plate 212. For example, the first cover 311 may be joined to the first plate 212. For example, the first cover 311 may provide a space for mounting the frame 313 thereon. For example, the first cover 311 may be joined to the frame 313.

For example, the first plate 212 may at least partially constitute a rear portion of the outer face. For example, the first plate 212 may include an opening 212a for the one or more rear cameras 250-2. For example, the first plate 212 may be disposed on the face of the first cover 311. For example, the opening 212a may be aligned with the opening 311a.

For example, the frame 313 may be at least partially surrounded by the first cover 311.

For example, the frame 313 may be at least partially surrounded by the display 230. For example, although the frame 313 is at least partially surrounded by the display 230, a position of the frame 313 may be maintained independently of the movement of the display 230. For example, the frame 313 may be arranged with respect to at least some of components of the display 230. For example, the frame 313 may include rails 313a which provide (or guide) a movement path of at least one component of the display 230.

For example, the frame 313 may be joined with at least one component of the electronic device 101. For example, the frame 313 may support a rechargeable battery 319. For example, the battery 319 may be supported through a hole or recess in a face 313b of the frame 313. For example, the frame 313 may fasten one end of a flexible printed circuit board (FPCB) 325, on the face of the frame 313. One end of the FPCB 325 may be electrically coupled to a motor 361. For example, although not explicitly shown in FIGS. 3A and 3B, the other end of the FPCB 325 may be coupled to a printed circuit board (PCB) 324 through at least one connector. For example, the PCB 324 may be electrically coupled to another PCB (not shown in FIGS. 3A and 3B) supplying power to the motor 361, through the FPCB 325.

For example, the frame 313 may be joined to at least one structure of the electronic device 101 for a plurality of states including the first state and the second state. For example, the frame 313 may fasten the motor 361 of the driving unit 360.

For example, the second housing 220 may be movably engaged with the first housing 210, and the second housing 220 may include a second cover 321 and a second plate 322.

For example, the second cover 321 may be at least partially surrounded by the display 230. For example, the second cover 321 may be joined at least a portion of a first region 230a of the display 230 surrounding the second cover 321, unlike the frame 313, so that the display 230 moves along the second housing 220 which moves with respect to the first housing 210.

For example, the second cover 321 may be joined with at least one component of the electronic device 101. For example, the second cover 321 may be joined with the PCB 324 including the components of the electronic device 101. For example, the PCB 324 may include the processor 120 (not shown in FIGS. 3A and 3B). For example, the second cover 321 may include the one or more rear cameras 250-2.

For example, the second cover 321 may be joined with at least one structure of the electronic device 101 for the plurality of states including the first state and the second state. For example, the second cover 321 may fasten a rack gear 363 of the driving unit 360.

For example, the motor 361 of the driving unit 360 may be fastened to the second cover 321, and the rack gear 363 of the driving unit 360 may be fastened to the frame 313.

For example, the second cover 321 may be joined with the second plate 322.

For example, the second plate 322 may be joined with at least one component of the electronic device 101, which is joined in the second cover 321, and/or the second cover 321 in order to protect at least one structure of the electronic device 101 joined in the second cover 321. For example, the second plate 322 may include a structure for the at least one component. For example, the second plate 322 may include one or more openings 327 and 328 for the one or more rear cameras 250-2. For example, the one or more openings 327 and 328 may be aligned with the one or more rear cameras 250-2 disposed on the second cover 321. For example, sizes the one or more openings 327 and 328 may correspond respectively to sizes of the one or more rear cameras 250-2.

For example, the display 230 may include a support member 331. For example, the support member 331 may include a plurality of bars. For example, the plurality of bars may be joined with each other. The support member 331 may support a second region 230b of the display 230.

For example, the driving unit 360 may include the motor 361, a pinion gear 362, and the rack gear 363.

For example, the motor 361 may operate, based on power from the battery 319. For example, the power may be provided to the motor 361, in response to the defined user input.

For example, the pinion gear 362 may be joined with the motor 361 through a shaft. For example, the pinion gear 362 may rotate, based on the operation of the motor 361, transferred through the shaft.

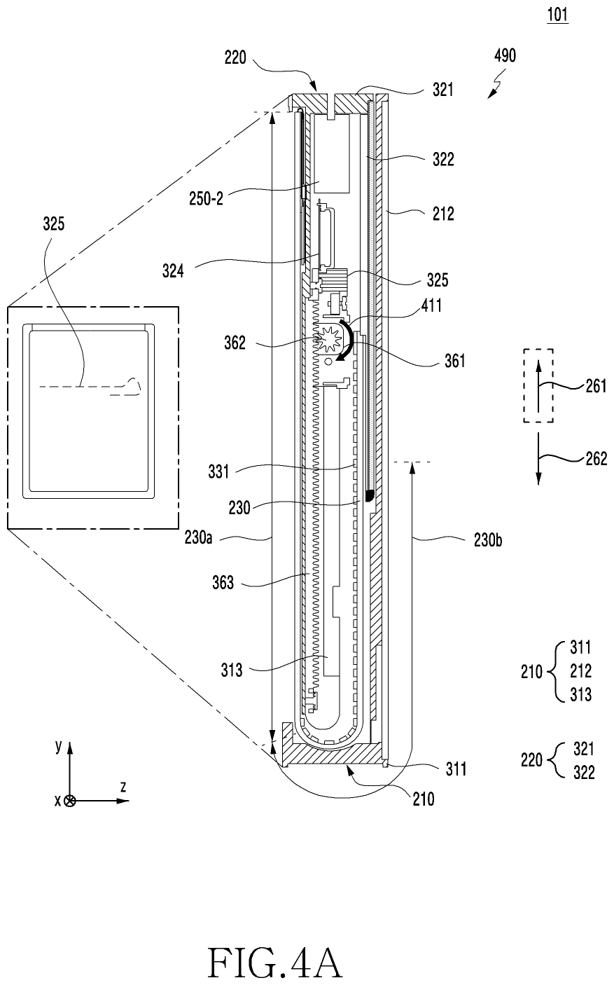

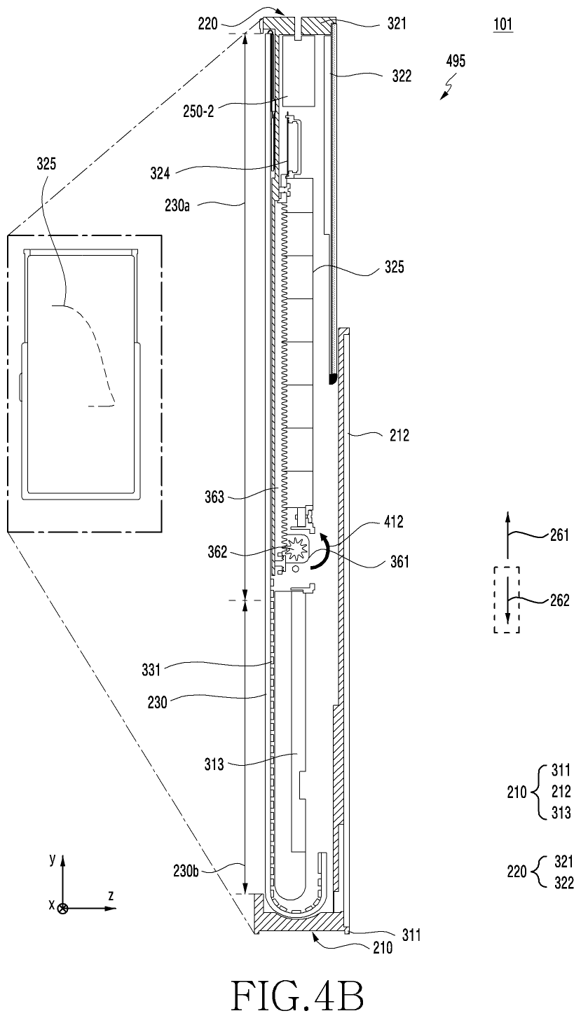

For example, the rack gear 363 may be arranged in relation to the pinion gear 362. For example, teeth of the rack gear 363 may be engaged with teeth of the pinion gear 362. For example, the rack gear 363 may move in a first direction 261 or a second direction 262, along a rotation of the pinion gear 362. For example, the second housing 220 may move in the first direction 261 and the second direction 262, by the rack gear 363 which moves depending on the rotation of the pinion gear 362, caused by the operation of the motor 361. For example, the first state of the electronic device 101 may change to a state (e.g., the one or more intermediary states or the second state) different from the first state, through the movement of the second housing 220 in the first direction 261. For example, the second state of the electronic device 101 may change to a state (e.g., the one or more intermediary states or the first state) different from the second state, through the movement of the second housing 220 in the second direction 262. For example, the changing of the first state to the second state by the driving unit 360 and the changing of the second state to the first state by the driving unit 360 may be exemplified through FIGS. 4A and 4B.

FIG. 4A is a cross-sectional view of an electronic device in a first state according to an embodiment of the disclosure. FIG. 4B is a cross-sectional view of an electronic device in a second state according to an embodiment of the disclosure.

Referring to FIGS. 4A and 4B, a motor 361 may operate, based at least in part on the defined user input received within a first state 490. For example, a pinion gear 362 may rotate in a first rotation direction 411, based at least in part on the operation of the motor 361. For example, a rack gear 363 may move in a first direction 261, based at least in part on the rotation of the pinion gear 362 in the first rotation direction 411. For example, since a second cover 321 in a second housing 220 fastens the rack gear 363, the second housing 220 may move in the first direction 261, based at least in part on the movement of the rack gear 363 in the first direction 261. For example, since the second cover 321 in the second housing 220 is joined with at least a portion of a first region 230a of the display 230 and fastens the rack gear 363, the display 230 may move in the first direction 261, based at least in part on the movement of the rack gear 363 in the first direction 261. For example, the display 230 may move along the rails 313a of FIG. 3B. For example, a support member 331 moves in the first direction 261 along the rails 313a, and thus the display 230 supported by the support member 331 may move in the first direction 261. For example, at least some of the plurality of bars of the support member 331 of the display 230 may change in shape, when the first state 490 changes to a second state 495.

For example, a second region 230b of the display 230 may move depending on the movement of the display 230. For example, the second region 230b may move through a space between a first cover 311 and a frame 313, when the first state 490 changes to the second state 495 according to the defined user input. For example, the second region 230b in the second state 495 may be exposed visually, unlike the second region 230b rolled into the space in the first state 490.

For example, since the second cover 321 in the second housing 220 is joined with the PCB 324 coupled to the other end of an FPCB 325 and fastens the rack gear 363, the FPCB 325 may change in shape, when the first state 490 changes to the second state 495.

The motor 361 may operate, based at least in part on the defined user input received in the second state 495. For example, the pinion gear 362 may rotate in a second rotation direction 412, based at least in part on the operation of the motor 361. For example, the rack gear 363 may move in a second direction 262, based at least in part on the rotation of the pinion gear 362 in the second rotation direction 412. For example, since the second cover 321 in the second housing 220 fastens the rack gear 363, the second housing 220 may move in the second direction 262, based at least in part on the movement of the rack gear 363 in the second direction 262. For example, since the second cover 321 in the second housing 220 is joined with at least a portion of the first region 230a of the display 230 and fastens the rack gear 363, the display 230 may move, based at least in part on the movement of the rack gear 363 in the second direction 262. The support member 331 moves in the second direction 262 along the rails 313a, and thus the display 230 supported by the support member 331 may move in the second direction 262. For example, the display 230 may move along rails (e.g., the rails 313a of FIG. 3B). For example, at least one of the plurality of bars of the support member 331 of the display 230 may change in shape, when the second state 495 changes to the first state 490. The support member 331 may move with respect to the first housing 210. The support member 331 accommodated in the first housing 210 in the first state 490 may be located between the first cover 311 and the frame 313. The display 230 may move with respect to the first housing 210 depending on the movement of the support member 331.

For example, the second region 230b of the display 230 may move depending on the movement of the display 230. For example, the second region 230b may move through a space between the first cover 311 and the frame 313, when the second state 495 changes to the first state 490 according to the defined user input. For example, the second region 230b in the first state 490 may be rolled into the space, unlike the second region 230b exposed visually in the second state 495.

For example, since the second cover 321 in the second housing 220 is joined with the PCB 324 coupled with the other end of the FPCB 325 and fastens the rack gear 363, the FPCB 325 may change in shape, when the second state 495 changes to the first state 490.

Although FIGS. 2A to 2D, 3A, 3B, 4A, and 4B illustrate the electronic device 101 in which a height of the display region changes and a width of the display region is maintained when the first state (or the second state) changes to the second state (or the first state) in a portrait mode, this is for convenience of explanation. For example, the electronic device 101 may be implemented such that the height of the display region is maintained and the width of the display region changes, when the first state (or the second state) changes to the second state (or the first state) in the portrait mode.

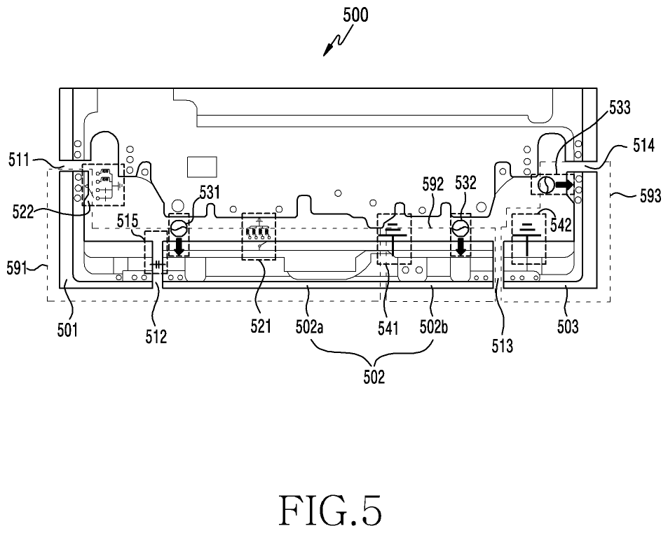

FIG. 5 is a drawing for explaining an antenna disposed on an electronic device according to an embodiment of the disclosure.

The electronic device of FIG. 5 and parts constituting the electronic device may respectively correspond to the electronic device 101 described above with reference to FIGS. 1, 2A to 2D, 3A, 3B, 4A, and 4B and parts constituting the electronic device 101.

According to an embodiment, the electronic device may include housing parts joined slidably. For example, the electronic device may include a second housing part 500 joined to be at least partially drawn into and/or drawn out with respect to a first housing part.

Referring to FIG. 5, a second housing part 500 may include conductive members 501, 502, and 503. For example, the second housing part 500 may include a first conductive member 501. For example, the second housing part 500 may include a second conductive member 502. For example, the second housing part 500 may include a third conductive member 503. For example, at least some of side members of the second housing part 500 may include a conductive material.

According to an embodiment, the second housing part 500 may include at least one of segments 511, 512, 513, and 514. For example, a first segment 511 may be located at a side member disposed to one side of the second housing part 500. For example, a fourth segment 514 may be located at a side member disposed to the other side of the second housing part 500. For example, a second segment 512 and a third segment 513 may be located at a side member disposed to a lower end of the second housing part 500.

According to an embodiment, the conductive members 501, 502, and 503 may be classified by the segments 511, 512, 513, and 514. For example, the first conductive member 501 may be classified by the first segment 511 and the second segment 512. For example, the second conductive member 502 may be classified by the second segment 512 and the third segment 513. For example, the third conductive member 503 may be classified by the third segment 513 and the fourth segment 514. For example, the first conductive member 501 and the second conductive member 502 may be classified by the second segment 512. For example, the second conductive member 502 and the third conductive member 503 may be classified by the third segment 513. According to an embodiment, the conductive members 501 and 502 may be coupled by at least one capacitive electrical element 515. For example, the first conductive member 501 and the second conductive member 502 may be coupled by a capacitive electrical element 515. For example, one side of the first conductive member 501 is coupled to one side of the capacitive electrical element 515 and one side of the second conductive member 502 is coupled to the other side of the capacitive electrical element 515, and thus the first conductive member 501 and the second conductive member 502 may be coupled.

According to an embodiment, the second housing part 500 may include one or more grounding portions 541 and 542. For example, the second housing part 500 may include a first grounding portion 541 coupled to the second conductive member 502. For example, the first grounding portion 541 may be disposed between the second segment 512 and the third segment 513. For example, the second housing part 500 may include a second grounding portion 542 coupled to the third conductive member 503. For example, the second grounding portion 542 may be disposed between the third segment 513 and the fourth segment 514. For example, the second grounding portion 542 may be disposed near the third segment 513.

According to an embodiment, the conductive member may be classified based on the grounding portion. For example, the second conductive member may be classified into a first portion 502a and a second portion 502b by the first grounding portion 541. For example, the first portion 502a of the second conductive member may be disposed to one side of the first grounding portion 541, and the second portion 502b of the second conductive member may be disposed to the other side of the first grounding portion 541.

According to an embodiment, the electronic device may transmit and/or receive a signal wirelessly through the conductive members 501, 502, and 503. That is, the conductive members 501, 502, and 503 may operate as antennas. For example, the first conductive member 501 and the first portion 502a of the second conductive member 502 may operate as a first antenna 591. For example, the second portion 502b of the second conductive member 502 may operate as a second antenna 592. For example, the third conductive member 503 may operate as a third antenna 593.

According to an embodiment, the second housing part 500 may include one or more feeding portions 531, 532, and 533. For example, the second housing part 500 may include a first feeding portion 531 coupled to the second conductive member 502. For example, the first feeding portion 531 may be disposed between the second segment 512 and the third segment 513. For example, the first feeding portion 531 may be disposed near the second segment 512. For example, the second housing part 500 may include a second feeding portion 532 coupled to the second conductive member 502. For example, the second feeding portion 532 may be disposed between the second segment 512 and the third segment 513. For example, the second feeding portion 532 may be disposed near the third segment 513. For example, the second feeding portion 532 may be disposed in a direction opposite the first feeding portion 531 with respect to the first grounding portion 541. For example, the second housing part 500 may include a third feeding portion 533 coupled to the third conductive member 503. For example, the third feeding portion 533 may be disposed between the third segment 513 and the fourth segment 514. For example, the third feeding portion 533 may be disposed near the fourth segment 514. For example, the third feeding portion 533 may be disposed closer to the fourth segment 514 than the second grounding portion 542. For example, the third feeding portion 533 may be disposed in a direction opposite the second feeding portion 532 with respect to the second grounding portion 542.

According to an embodiment, the conductive members 501, 502, and 503 of the second housing part 500 may operate as antennas by being supplied with electricity by the feeding portions 531, 532, and 533. For example, the electronic device may feed power to the feeding portions 531, 532, and 533 through a PCB mounted on the second housing part 500. For example, the first conductive member 501 and the first portion 502a of the second conductive member 502 may operate as a first antenna by being supplied with electricity from the first feeding portion 531. For example, the second portion 502b of the second conductive member 502 may operate as a second antenna by being supplied electricity from the second feeding portion 532. For example, the third conductive member 503 may operate as a third antenna by being supplied with electricity from the third feeding portion 533.

According to an embodiment, the electronic device may transmit and receive a wireless signal by using the first antenna 591. For example, the electronic device may transmit and receive the wireless signal by using the first conductive member 501 and the first portion 502a of the second conductive member 502 between the first segment 511 and the third segment 513. For example, the electronic device may transmit and receive a wireless signal of a low-band (e.g., a frequency band of 1 gigahertz (GHz) or less), by using the first conductive member 501 and the first portion 502a of the second conductive member between the first segment 511 and the first grounding portion 541.

According to an embodiment, the electronic device may transmit and receive a wireless signal by using the second antenna 592. For example, the electronic device may transmit and receive a wireless signal of a mid-band and/or high-band by using the second portion 502b of the second conductive member 502 between the first grounding portion 541 and the third segment 513. For example, the electronic device may transmit and receive a wireless signal by using the second portion 502b of the second conductive member 502 and a portion of the third conductive member 503 between the first grounding portion 541 and the second grounding portion 542.

According to an embodiment, the electronic device may transmit and receive a wireless signal by using the third antenna 593. For example, the electronic device may transmit and receive a wireless signal of a high-band by using the third conductive member 503 between the third segment 513 and the fourth segment 514. For example, the electronic device may transmit and receive a wireless signal, by using the third conductive member 503 between the second grounding portion 542 and the fourth segment 514.

According to an embodiment, the conductive member of the second housing part 500 may be coupled with at least one element. For example, in the second housing part 500, the second conductive member 502 between the second segment 512 and the third segment 513 may be coupled with at least one element through a first switching module 521. For example, the first switching module 521 may be coupled to the first portion 502a of the second conductive member 502 between the first feeding portion 531 and the first grounding portion 541. For example, the first switching module 521 may couple at least one element (e.g., an inductance element, a capacitance element), which changes a resonance frequency of the first antenna 591, and the second conductive member 502. For example, the first switching module 521 may couple an element (e.g., an inductance element, a capacitance element) for matching an impedance of the first antenna 591 to a specific impedance value and the second conductive member 502. For example, in the second housing part 500, the first conductive member 501 between the first segment 511 and the second segment 512 may be coupled to at least one element through a second switching module 522. For example, the second switching module 522 may be coupled to the first conductive member 501 in the vicinity of the first segment 511. For example, the second switching module 522 may couple at least one element (e.g., an inductance element, a capacitance element), which changes a resonance frequency of the first antenna 591, and the conductive member. For example, the second switching module 522 may couple an element (e.g., an inductance element, a capacitance element) for matching an impedance of the first antenna 591 to a specific impedance value and the conductive member.

According to an embodiment, the electronic device may change a frequency band for transmitting and receiving a signal by coupling the conductive member with at least one element. For example, the electronic device may couple the second conductive member 502 and a first element by using the first switching module 521, thereby low-shifting or high-shifting the resonance frequency of the first antenna 591. For example, the electronic device may couple the first conductive member 501 and a second element by using the second switching module 522, thereby low-shifting or high-shifting the resonance frequency of the first antenna 591. For example, the electronic device may couple an inductance element to the first conductive member 501, thereby low-shifting the resonance frequency of the first antenna 591. For example, the electronic device may couple a capacitance element to the first conductive member 501, thereby high-shifting the resonance frequency of the first antenna 591.

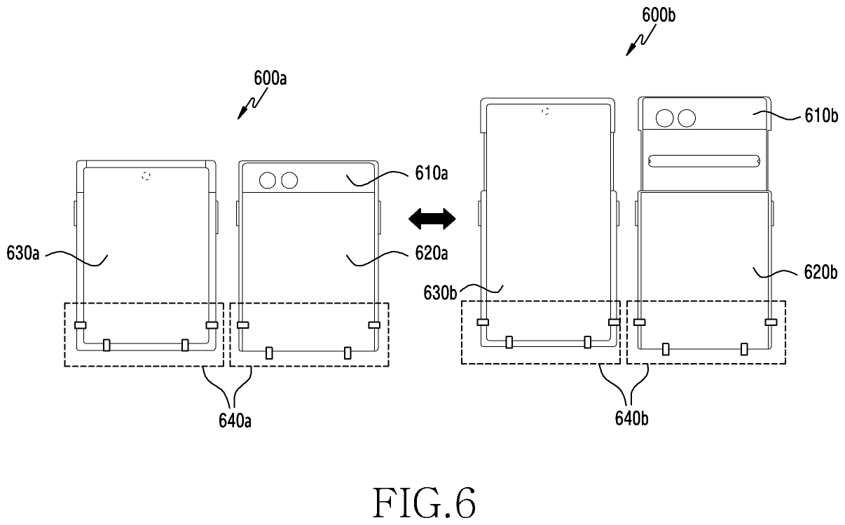

FIG. 6 is a drawing for explaining antenna performance depending on a state change of an electronic device from a first state to a second state according to an embodiment of the disclosure.

The electronic device of FIG. 6 and parts constituting the electronic device may respectively correspond to the electronic device 101 described above with reference to FIGS. 1, 2A to 2D, 3A, 3B, 4A, and 4B and parts constituting the electronic device 101. The conductive member illustrated in FIG. 6 may correspond to the conductive member described above with reference to FIG. 5.

Referring to FIG. 6, electronic devices 600a and 600b may be in a first state and a second state. For example, the electronic devices 600a and 600b may be joined movably with first housing parts 610a and 610b between a retracted position and extended position of second housing parts 620a and 620b. For example, the first state of the electronic device 600a may be a state of the electronic device 101 described with reference to FIGS. 2A and 2B. For example, the first state of the electronic device 600a may be in a state where the first housing part 610a is drawn into the second housing part 620a.

For example, the first state of the electronic device 600a may be a state where the second housing part 620a is retracted with respect to the first housing part 610a. For example, the second state of the electronic device 600b may be a state of the electronic device 101 described with reference to FIGS. 2C and 2D. For example, the second state of the electronic device 600b may be a state where the first housing part 601b is drawn out from the second housing part 620b. For example, the second state of the electronic device 600b may be a state where the second housing part 620b moves to an extended position with respect to the first housing part 610b.

According to an embodiment, flexible displays 630a and 630b may be drawn into the second housing parts 620a and 620b. For example, the flexible displays 630a and 630b may be rolled inside the second housing parts 620a and 620b by being joined with a support member (e.g., the support member 331 of FIG. 3). For example, a portion of the flexible displays 630a and 630b may be rolled toward a rear side of the second housing parts 620a and 620b inside the second housing parts 620a and 620b.

According to an embodiment, the flexible displays 630a and 630b may be joined with the first housing parts 610a and 610b. For example, the other end of the flexible displays 630a and 630b may be joined with the first housing parts 610a and 610b by being pressed against the first housing parts 610a and 610b.

According to an embodiment, the flexible displays 630a and 630b may be joined with the second housing parts 620a and 620b. For example, the support member joined with at least a portion of the rear face of the flexible displays 630a and 630b may be joined with a rail disposed to one side or both sides of the second housing parts 620a and 620b. The rail joined with the support member may be joined with a guide joined to the first housing parts 610a and 610b. For example, the guide may be joined in an engaged manner to the rail to linearly move along a lengthwise direction of the second housing parts 620a and 620b.

According to an embodiment, in the flexible displays 630a and 630b, a size of a region exposed to the outside may change when the second housing parts 620a and 620b move with respect to the first housing parts 610a and 610b. For example, an actuator coupled to the first housing parts 610a and 610b may allow the rail to move. In accordance with the rail moving with respect to the guide, the support member joined to the rail may be rolled or unrolled. For example, when the second housing part 620b moves to an extended position, the support member joined to the rail may move so that a portion of the flexible display 630b rolled inside the second housing part 620b is unrolled. One end of the flexible display 630b may move close to a lower end of the second housing part 620b along a direction of the second housing part 620b. For example, when the second housing part 620a moves to a retracted position, the support member joined to the rail may move so that a portion of the flexible display 630a exposed to the outside is rolled inside the second housing part 620a. One end of the flexible display 630a may move away from the lower end of the second housing part 620a along the lengthwise direction of the second housing part 620a. For example, one end of the flexible displays 630a and 630b may move close to a rear side of the second housing parts 620a and 620b. For example, one end of the flexible displays 630a and 630b may move parallel with the rear side of the second housing parts 620a and 620b in a state of being spaced apart by a specific distance from the rear side of the second housing parts 620a and 620b.

According to an embodiment, when the second housing parts 620a and 620b move with respect to the first housing parts 610a and 610b, there may be an electrical change in the electronic devices 600a and 600b. For example, a length of the electronic device 600b may increase upon changing from the electronic device 600a of the first state to the electronic device 600b of the second state. The increase in the length of the electronic device 600b may result in an increase in a ground area of an antenna of the electronic device 600b and/or an electrical length of the antenna. For example, when the second housing parts 620a and 620b move with respect to the first housing parts 610a and 610b, there may be a capacitance change between the flexible displays 630a and 630b and the second housing parts 620a and 620b disposed to lower portions 640a and 640b of the second housing parts 620a and 620b. For example, a resonance frequency of a first antenna (e.g., 591 of FIG. 5) which transmits and receives a signal through a conductive member may change, due to an electrical change (e.g., a length of a ground of the electronic device, a ground area of the antenna, an electrical length of the antenna, a capacitance change) depending on a state change of the electronic devices 600a and 600b.

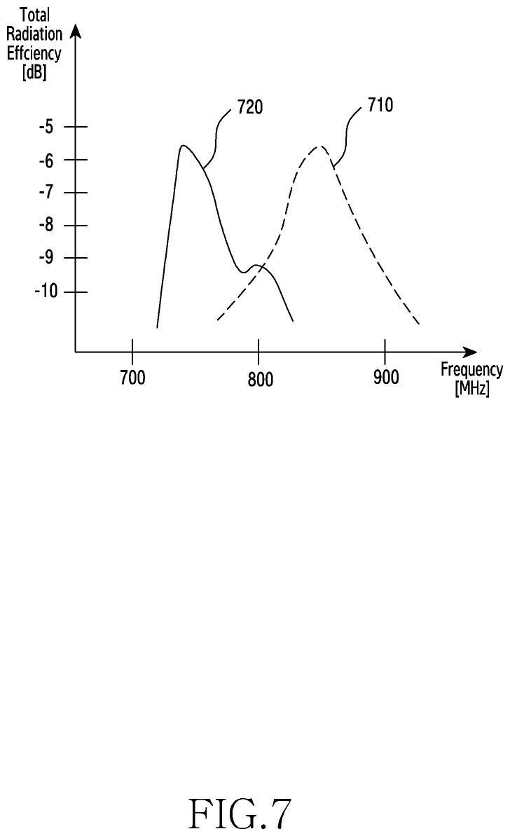

FIG. 7 is a drawing for comparative description of antenna performance when an electronic device is in a first state and antenna performance when the electronic device is in a second state according to an embodiment of the disclosure.

A resonance frequency of a first antenna (e.g., 591 of FIG. 5) when the electronic device of FIG. 6 is in the first state and a resonance frequency of the first antenna (e.g., 591 of FIG. 5) when the electronic device is in the second state are compared in FIG. 7.

According to an embodiment, the first antenna (e.g., 591 of FIG. 5) may be designed to transmit and receive a signal at a most efficient frequency. The most efficient frequency may correspond to the resonance frequency of the first antenna (e.g., 591 of FIG. 5).

Referring to FIG. 7, a first graph 710 illustrates per-frequency efficiency of a first antenna (e.g., 591 of FIG. 5) including a conductive member (e.g., in lower portion 640a of FIG. 6), when the electronic device is in the first state (e.g., the first state of the electronic device described with reference to FIGS. 2A and 2B). Referring to the first graph 710, the first antenna (e.g., 591 of FIG. 5) may show high efficiency at a frequency band of about 850 megahertz (MHz). The first antenna (e.g., 591 of FIG. 5) may be designed to transmit and receive a signal at the frequency band of about 850 MHz.

Referring to FIG. 7, a second graph 720 illustrates per-frequency efficiency of the first antenna (e.g., 591 of FIG. 5) including a conductive member (e.g., in lower portion 640b of FIG. 6), when the electronic device is in the second state (e.g., the second state of the electronic device described with reference to FIGS. 2C and 2D). Referring to the second graph 720, the first antenna (e.g., 591 of FIG. 5) may show high efficiency at a frequency band of about 750 MHz.

Comparing the second graph 720 and the first graph 710, it may be confirmed that the resonance frequency of the first antenna (e.g., 591 of FIG. 5) is shifted from a frequency band of about 850 MHz to about 750 MHz in a case where an electronic device (e.g., 600b of FIG. 6) is in the second state, compared to a case where an electronic device (e.g., 600a of FIG. 6) is in the first state.

According to an embodiment, the state change of the electronic device (e.g., 600a, 600b) from the first state to the second state may result in an increase in a length of the electronic device (e.g., 600b) and an electrical length of the electronic device 600b. The increase in the electrical length of the electronic device (e.g., 600b) may result in an increase in a ground area of the first antenna (e.g., 591 of FIG. 5). The increase in the ground area of the first antenna (e.g., 591 of FIG. 5) may result in a low-shift for a resonance frequency of the first antenna (e.g., 591 of FIG. 5). The state change of the electronic device (e.g., 600a, 600b) from the first state to the second state may result in the low-shift for the resonance frequency of the first antenna (e.g., 591 of FIG. 5) due to the increase in the ground area of the first antenna (e.g., 591 of FIG. 5), despite a capacitance decrease between a second housing part (e.g., 620a, 620b) and a flexible display (e.g., 630a, 630b).

According to an embodiment, the state change of the electronic device (e.g., 600a, 600b) from the second state to the first state may result in a decrease in a length and electrical length of the electronic device (e.g., 600a). The decrease in the length of the electronic device (e.g., 600a) may result in a decrease in a ground area of the first antenna (e.g., 591 of FIG. 5). The decrease in the ground area of the first antenna (e.g., 591 of FIG. 5) may result in a high-shift for a resonance frequency of the first antenna (e.g., 591 of FIG. 5). The state change of the electronic device (e.g., 600a, 600b) from the second state to the first state may result in the high-shift for the resonance frequency of the first antenna (e.g., 591 of FIG. 5) due to the decrease in the ground area of the first antenna (e.g., 591 of FIG. 5), despite an increase in capacitance between the second housing part (e.g., 620a, 620b) and the flexible display (e.g., 630a, 630b).

Referring to FIG. 7, it may be difficult for the electronic device (e.g., 600b of FIG. 6) in the second state to transmit and receive a signal at a frequency band of about 850 MHz by using the first antenna (e.g., 591 of FIG. 5) designed to transmit and receive the signal through the frequency band of about 850 MHz. That is, the first antenna (e.g., 591 of FIG. 5) may decrease in performance.

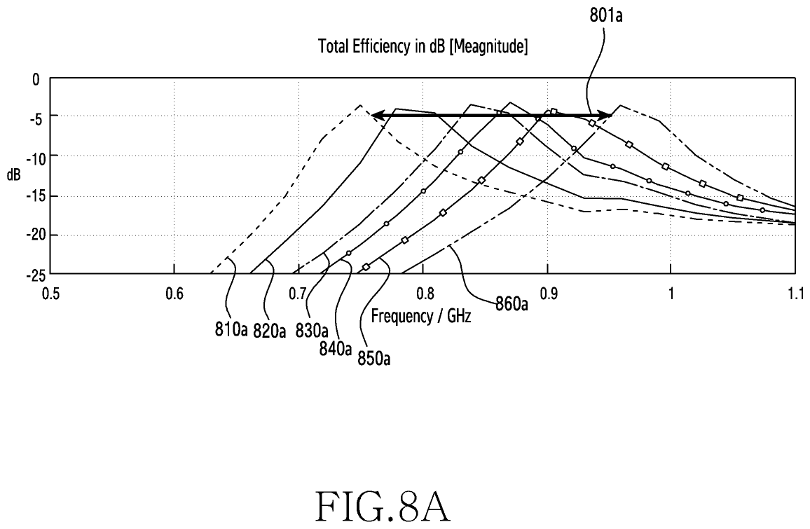

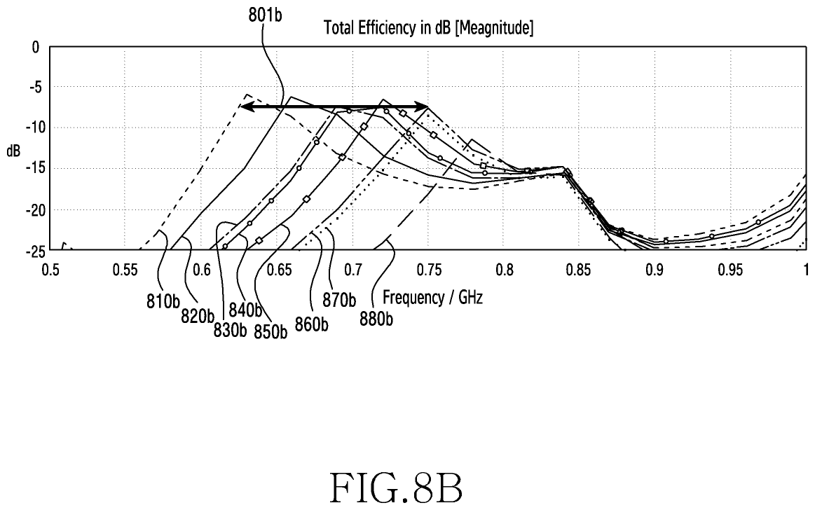

FIG. 8A is a drawing for explaining performance of a first antenna (e.g., 591 of FIG. 5) of which an element is coupled, when an electronic device is in a first state according to an embodiment of the disclosure.

Performance of the first antenna (e.g., 591 of FIG. 5) of which an element is coupled to a conductive member through the first switching module 521 and second switching module 522 of FIG. 5 is described in FIG. 8A for the electronic device (e.g., 600a of FIG. 6) in the first state.

Referring to FIG. 8A, a first graph 810a illustrates per-frequency efficiency of a first antenna (e.g., 591 of FIG. 5), when only an inductive element of 20 nanohenry (nH) is joined to a conductive member through a first switching module. Referring to the first graph 810a, the first antenna (e.g., 591 of FIG. 5) may show high efficiency at a frequency band of about 730 MHz.

Referring to FIG. 8A, a second graph 820a illustrates per-frequency efficiency of a first antenna (e.g., 591 of FIG. 5), when only an inductive element of 10 nH is joined to a conductive member through a first switching module. Referring to the second graph 820a, the first antenna (e.g., 591 of FIG. 5) may show high efficiency at a frequency band of about 780 MHz.

Referring to FIG. 8A, a third graph 830a illustrates per-frequency efficiency of a first antenna (e.g., 591 of FIG. 5), when only an inductive element of 5 nH is joined to a conductive member through a first switching module. Referring to the third graph 830a, the first antenna (e.g., 591 of FIG. 5) may show high efficiency at a frequency band of about 820 MHz.

Referring to FIG. 8A, a fourth graph 840a illustrates per-frequency efficiency of a first antenna (e.g., 591 of FIG. 5), when an inductive element of 20 nH is joined to a conductive member through a first switching module and an element for impedance matching is joined to the conductive member through a second switching module. Referring to the fourth graph 840a, the first antenna (e.g., 591 of FIG. 5) may show high efficiency at a frequency band of about 860 MHz.

Referring to FIG. 8A, a fifth graph 850a illustrates per-frequency efficiency of a first antenna (e.g., 591 of FIG. 5), when an inductive element of 10 nH is joined to a conductive member through a first switching module and an element for impedance matching is joined to the conductive member through a second switching module. Referring to the fifth graph 850a, the first antenna (e.g., 591 of FIG. 5) may show high efficiency at a frequency band of about 900 MHz.

Referring to FIG. 8A, a sixth graph 860a illustrates per-frequency efficiency of a first antenna (e.g., 591 of FIG. 5), when an inductive element of 5 nH is joined to a conductive member through a first switching module and an element for impedance matching is joined to the conductive member through a second switching module. Referring to the sixth graph 860a, the first antenna (e.g., 591 of FIG. 5) may show high efficiency at a frequency band of about 960 MHz.

Referring to the first graph 810a to the sixth graph 860a, the electronic device (e.g., 600a of FIG. 6) in the first state may couple at least one element to the conductive member by using the first switching module and the second switching module, thereby transmitting and receiving a signal by using a frequency bandwidth 801a between about 730 MHz and about 960 MHz.

FIG. 8B is a drawing for explaining performance of a first antenna (e.g., 591 of FIG. 5) of which an element is coupled, when an electronic device is in a second state according to an embodiment of the disclosure.

Performance of the first antenna (e.g., 591 of FIG. 5) of which an element is coupled to a conductive member through the first switching module 521 and second switching module 522 of FIG. 5 is described in FIG. 8B for the electronic device (e.g., 600b of FIG. 6) in the second state.

Referring to FIG. 8B, a first graph 810b illustrates per-frequency efficiency of a first antenna (e.g., 591 of FIG. 5), when only an inductive element of 20 nH is joined to a conductive member through a first switching module. Referring to the first graph 810b, the first antenna (e.g., 591 of FIG. 5) may show high efficiency at a frequency band of about 630 MHz.

Referring to FIG. 8B, a second graph 820b illustrates per-frequency efficiency of a first antenna (e.g., 591 of FIG. 5), when only an inductive element of 10 nH is joined to a conductive member through a first switching module. Referring to the second graph 820b, the first antenna (e.g., 591 of FIG. 5) may show high efficiency at a frequency band of about 660 MHz.

Referring to FIG. 8B, a third graph 830b illustrates per-frequency efficiency of a first antenna (e.g., 591 of FIG. 5), when only an inductive element of 5 nH is joined to a conductive member through a first switching module. Referring to the third graph 830b, the first antenna (e.g., 591 of FIG. 5) may show high efficiency at a frequency band of about 690 MHz.

Referring to FIG. 8B, a fourth graph 840b illustrates per-frequency efficiency of a first antenna (e.g., 591 of FIG. 5), when an inductive element of 20 nH is joined to a conductive member through a first switching module and an element for impedance matching is joined to the conductive member through a second switching module. Referring to the fourth graph 840b, the first antenna (e.g., 591 of FIG. 5) may show high efficiency at a frequency band of about 720 MHz.

Referring to FIG. 8B, a fifth graph 850b illustrates per-frequency efficiency of a first antenna (e.g., 591 of FIG. 5), when an inductive element of 10 nH is joined to a conductive member through a first switching module and an element for impedance matching is joined to the conductive member through a second switching module. Referring to the fifth graph 850b, the first antenna (e.g., 591 of FIG. 5) may show high efficiency at a frequency band of about 720 MHz.

Referring to FIG. 8B, a sixth graph 860b illustrates per-frequency efficiency of a first antenna (e.g., 591 of FIG. 5), when an inductive element of 5 nH is joined to a conductive member through a first switching module and an element for impedance matching is joined to the conductive member through a second switching module. Referring to the sixth graph 860b, the first antenna (e.g., 591 of FIG. 5) may show high efficiency at a frequency band of about 750 MHz.

Referring to FIG. 8B, a seventh graph 870b illustrates per-frequency efficiency of a first antenna (e.g., 591 of FIG. 5), when only an inductive element of 1 nH is joined to a conductive member through a first switching module. Referring to the seventh graph 870b, the first antenna (e.g., 591 of FIG. 5) may show high efficiency at a frequency band of about 750 MHz.

Referring to FIG. 8B, an eighth graph 880b illustrates per-frequency efficiency of a first antenna (e.g., 591 of FIG. 5), when an inductive element of 1 nH is joined to a conductive member through a first switching module and an element for impedance matching is joined to the conductive member through a second switching module. Referring to the eighth graph 880b, the first antenna (e.g., 591 of FIG. 5) may show high efficiency at a frequency band of about 770 MHz. In this case, however, it is difficult for the first antenna (e.g., 591 of FIG. 5) to transmit and receive a signal with efficiency of about −12 decibels (dB).

Referring to the first graph 810b to the eighth graph 880b, the electronic device (e.g., 600a of FIG. 6) in the second state may couple at least one element to the conductive member by using the first switching module and the second switching module, thereby transmitting and receiving a signal by using a frequency bandwidth 801b between about 630 MHz and about 750 MHz.

Referring to FIGS. 8A and 8B, in the electronic device (e.g., 600a, 600b of FIG. 6), an electrical change of the electronic device (e.g., 600a, 600b of FIG. 6) may occur due to a state change of the electronic device (e.g., 600a, 600b of FIG. 6). For example, an electrical length of the electronic device (e.g., 600b of FIG. 6) in the second state may be increased compared to the electronic device (e.g., 600a of FIG. 6) in the first state. For example, capacitance produced between a flexible display (e.g., 630a, 630b of FIG. 6) and a first antenna (e.g., 591 of FIG. 5) located at a lower end of a second housing part (e.g., 500 of FIG. 5) may be reduced more in the electronic device (e.g., 600b of FIG. 6) in the second state than in the electronic device (e.g., 600a of FIG. 6) in the first state.

Referring to FIGS. 8A and 8B, in the electronic device, the flexible display may be drawn out from the second housing part, thereby increasing an electrical length of the electronic device (e.g., 600b of FIG. 6) and decreasing capacitance between the second housing part and the flexible display. Although the capacitance between the second housing part and the flexible display is reduced more in the electronic device in the second state than in the electronic device in the first state, a resonance frequency of the first antenna (e.g., 591 of FIG. 5) of the electronic device (e.g., 600b of FIG. 6) in the second state may be low-shifted, due to an increase in the electrical length of the electronic device.

Referring to FIGS. 8A and 8B, the resonance frequency of the first antenna (e.g., 591 of FIG. 5) may change depending on the state (e.g., the first state and the second state) of the electronic device (e.g., 600a, 600b of FIG. 6). The bandwidth of the first antenna (e.g., 591 of FIG. 5) may change depending on the state (e.g., the first state and the second state) of the electronic device. For example, although the first antenna (e.g., 591 of FIG. 5) of the electronic device (e.g., 600a of FIG. 6) in the first state transmits and receives a signal through a frequency bandwidth 801 between about 730 MHz and about 960 MHz, the first antenna (e.g., 591 of FIG. 5) of the electronic device (e.g., 600b of FIG. 6) in the second state may transmit and receive the signal through a frequency bandwidth 901 of about 630 MHz to about 750 MHz. That is, the flexible display may be drawn out from the second housing part, thereby reducing the frequency bandwidth for transmitting and receiving the signal in the electronic device (e.g., 600b of FIG. 6) of which the electrical length is increased.

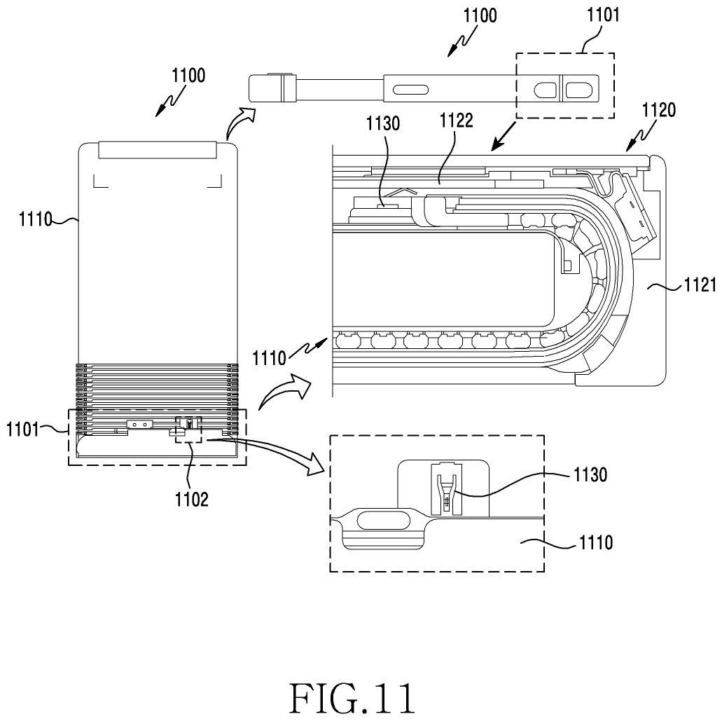

Referring to FIGS. 8A and 8B, the resonance frequency and bandwidth of the first antenna (e.g., 591 of FIG. 5) change depending on the state (e.g., the first state and the second state) of the electronic device, and thus the electronic device (e.g., 600a, 600b of FIG. 6) may not be able to transmit and receive a radio wave at a constant frequency. For example, it may be difficult for the electronic device (e.g., 600b of FIG. 6) in the second state to transmit and receive a signal by using a frequency band of 800 MHz to 960 MHz, even when at least one element is coupled to the conductive member by using the first switching module and the second switching module. Therefore, it may be difficult for the electronic device in the second state to use a wireless communication service using the frequency band of 800 MHz to 960 MHz. Therefore, regardless of the state (e.g., the first state and the second state) of the electronic device, it is necessary to stably transmit and receive a signal at a constant frequency band. For example, a conductive coupling member (e.g., 1130 of FIG. 11) described below with reference to FIG. 11 may couple a second housing part (e.g., 1120 of FIG. 11) and a flexible display (e.g., 1110 of FIG. 11), and thus the signal may be stably transmitted and received at the constant frequency band, regardless of the state (e.g., the first state and the second state) of the electronic device.

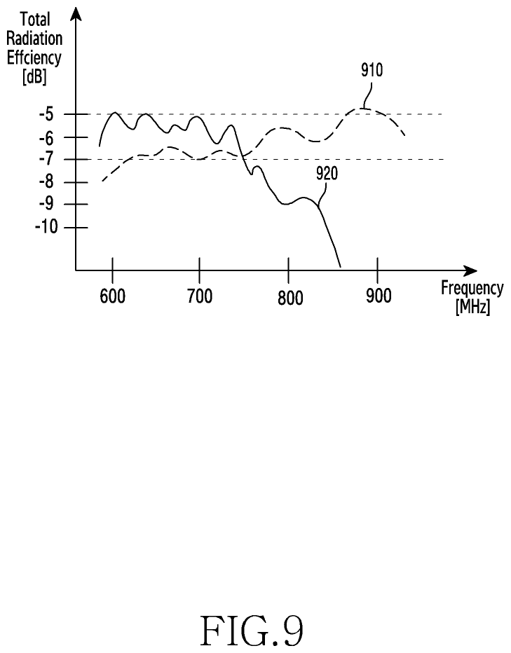

FIG. 9 is a drawing for comparative description of antenna performance when an electronic device is in a first state and antenna performance when the electronic device is in a second state according to an embodiment of the disclosure.

A frequency band at which an antenna having an element coupled to a conductive member through the first switching module 521 and second switching module 522 of FIG. 5 is able to transmit and receive a signal is compared in FIG. 9, according to the state (e.g., the first state, the second state) of the electronic device.

According to an embodiment, the electronic device may transmit and receive a signal by using an antenna with respect to a frequency band having antenna efficiency of at least −7 dB. For example, the electronic device may control the antenna not to able to transmit and receive the signal at the frequency band having the antenna efficiency equal to or less than −7 dB for such a reason as power consumption.

Referring to FIG. 9, a first graph 910 illustrates performance of an antenna of which an antenna is coupled to a conductive member through the first switching module 521 and second switching module 522 of FIG. 5 in an electronic device (e.g., 600a of FIG. 6) in a first state. Referring to the first graph 910, the electronic device in the first state may transmit and receive a signal at a frequency band of 630 MHz to 960 MHz, by coupling the element to the conductive member through the first switching module 521 and the second switching module 522.

Referring to FIG. 9, a second graph 920 illustrates performance of an antenna of which an antenna is coupled to a conductive member through the first switching module 521 and second switching module 522 of FIG. 5 in an electronic device (e.g., 600b of FIG. 6) in a second state. Referring to the second graph 920, the electronic device in the second state may transmit and receive a signal at a frequency band of 690 MHz to 750 MHz, by coupling the element to the conductive member through the first switching module 521 and the second switching module 522.

In the electronic device, the flexible display may be drawn out from the second housing part, thereby increasing an electrical length of the electronic device (e.g., 600b of FIG. 6) and decreasing capacitance between a second housing part and a flexible display. Although the capacitance between the second housing part and the flexible display is reduced more in the electronic device in the second state than in the electronic device in the first state, a resonance frequency of a first antenna (e.g., 591 of FIG. 5) of the electronic device (e.g., 600b of FIG. 6) in the second state may be low-shifted, due to an increase in the electrical length of the electronic device. It may be difficult for the electronic device (e.g., 600b of FIG. 6) in the second state to transmit and receive a signal by using a frequency band of 750 MHz to 960 MHz, even when at least one element is coupled to the conductive member by using the first switching module and the second switching module. Therefore, it may be difficult for the electronic device in the second state to use a wireless communication service using the frequency band of 750 MHz to 960 MHz. Therefore, regardless of the state (e.g., the first state and the second state) of the electronic device, it is necessary to stably transmit and receive a signal at a constant frequency band. For example, a conductive coupling member (e.g., 1130 of FIG. 11) described below with reference to FIG. 11 may couple a second housing part (e.g., 1120 of FIG. 11) and a flexible display (e.g., 1110 of FIG. 11), and thus the signal may be stably transmitted and received at the constant frequency band, regardless of the state (e.g., the first state and the second state) of the electronic device.

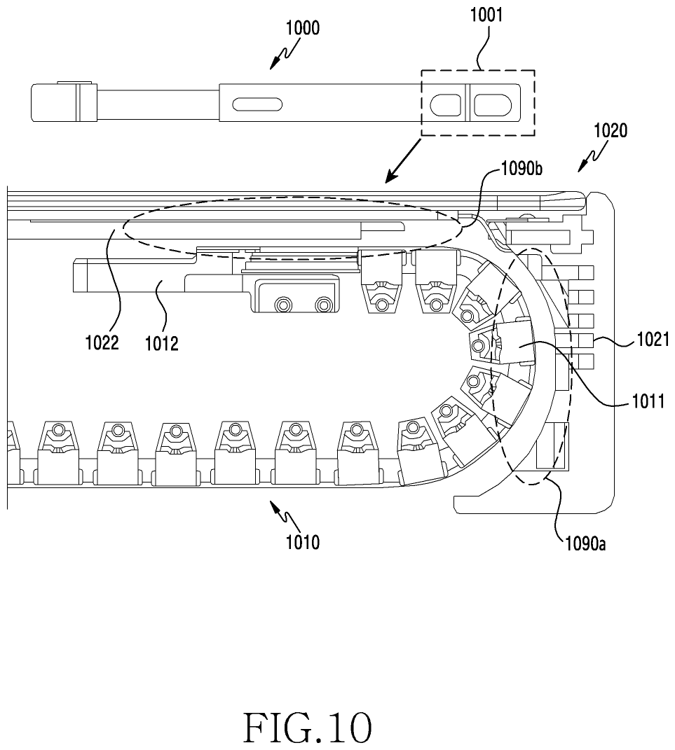

FIG. 10 is a drawing for explaining a cross-section of an electronic device according to an embodiment of the disclosure.

An electronic device 1000 of FIG. 10 and parts constituting the electronic device 1000 may respectively correspond to the electronic device 101 described above with reference to FIGS. 1, 2A to 2D, 3A, 3B, 4A, and 4B and parts constituting the electronic device 101.

Referring to FIG. 10, a flexible display 1010 may be drawn into a second housing part 1020. For example, even if an electronic device 1000 of which a first housing part is drawn out from the second housing part 1020 is in a second state, a portion of the flexible display 1010 may be drawn into the second housing part 1020.

According to an embodiment, a portion of the flexible display 1010 may be rolled. For example, a portion 1011 of the flexible display 1010 may be rolled in a lower portion 1001 of the second housing part 1020 toward a rear side 1022 of the second housing part 1020. For example, in the flexible display 1010, a portion of the rear face may be joined with the support member. For example, the support member joined with at least a portion of the rear face of the flexible display may be joined with a rail disposed to one side or both sides of the second housing part 1020. For example, a portion of the flexible display 1010 joined with the support member may be rolled toward the rear side 1022 of the second housing part 1020 along a rail.

According to an embodiment, one end 1012 of the flexible display 1010 may move along a lengthwise direction of the second housing part 1020. For example, when the electronic device is in a first state, the one end 1012 of the flexible display 1010 may move away from a lower end 1021 of the second housing part 1020 along the lengthwise direction of the second housing part 1020. For example, when the electronic device is in the second state, the one end 1012 of the flexible display 1010 may move close to the lower end 1021 of the second housing part 1020 along the lengthwise direction of the second housing part 1020. For example, the one end 1012 of the flexible display 1010 may move close to the rear side 1022 of the second housing part 1020. For example, one end of the flexible display 1010 may move parallel with the second housing part 1020 in a state of being spaced apart by a specific distance from the rear side 1022 of the second housing part 1020.

According to an embodiment, a portion of the flexible display 1010 may be coupled with the second housing part 1020. For example, the rolled portion 1011 of the flexible display 1010 may be coupled in a first region 1090a with the lower end 1021 of the second housing part 1020, thereby producing capacitance. For example, the rear side 1022 of the second housing part 1020 may be coupled with the flexible display 1010. For example, the rear side 1022 of the second housing part 1020 may be coupled in a second region 1090b with a portion of the flexible display 1010 located within a specific distance to the rear side 1022 of the second housing part 1020. For example, the rear side 1022 of the second housing part 1020 may be coupled with the one end 1012 of the flexible display 1010, thereby producing capacitance.

According to an embodiment, when the electronic device 1000 changes from the first state to the second state, there may be a change in capacitance between the flexible display 1010 and the second housing part 1020. For example, a decrease in a portion of the flexible display 1010 located within the specific distance to the rear side 1022 of the second housing part 1020 in the second region 1090b may result in a decrease in the capacitance between the flexible display 1010 and the second housing part 1020.

According to an embodiment, the state change of the electronic device 1000 may result in a change in a resonance frequency of an antenna. For example, the change in the state (e.g., the first state, the second state) of the electronic device 1000 may result in a change in a length and electrical length of the electronic device 1000. The change in the electrical length of the electronic device 1000 may result in the change in the resonance frequency of the antenna.

For example, the state change of the electronic device 1000 from the first state to the second state may result in a low-shift for the resonance frequency of the antenna. For example, an increase in an electrical length of the electronic device 1000 may result in the low-shift for the resonance frequency of the antenna. For example, due to the state change of the electronic device 1000 from the first state to the second state, the increased electrical length of the electronic device 1000 may provide a lengthened ground to an antenna disposed to a lower end of the electronic device 1000. Since the antenna disposed to the lower end of the electronic device 1000 transmits and receives a signal by using a low-band frequency, the resonance frequency of the antenna may be low-shifted due to the increased electrical length of the electronic device 1000.

For example, the state change of the electronic device 1000 from the second state to the first state may result in a high-shift for the resonance frequency of the antenna. For example, the decrease in the electrical length of the electronic device 1000 may result in the high-shift for the resonance frequency of the antenna. For example, due to the state change of the electronic device 1000 from the second state to the first state, the decreased electrical length of the electronic device 1000 may provide a shortened ground to the antenna disposed to the lower end of the electronic device 1000. Since the antenna disposed to the lower end of the electronic device 1000 transmits and receives a signal by using a low-band frequency, the resonance frequency of the antenna may be high-shifted due to the decreased electrical length of the electronic device 1000.

As described above with reference to FIGS. 7, 8A, 8B, and 9, the resonance frequency of the antenna changes depending on the state change of the electronic device, and thus it may be difficult for the electronic device to provide constant antenna performance.

FIG. 11 is a drawing for explaining a conductive coupling member of an electronic device according to an embodiment of the disclosure.

The electronic device of FIG. 11 and parts constituting the electronic device may respectively correspond to the electronic device 101 described above with reference to FIGS. 1, 2A to 2D, 3A, 3B, 4A, and 4B and parts constituting the electronic device 101.

Referring to FIG. 11, a flexible display 1110 may be drawn into a second housing part 1120. For example, even if an electronic device 1100 of which a first housing part is drawn out from the second housing part 1120 is in a second state, a portion of the flexible display 1110 may be drawn into the second housing part 1120.

According to an embodiment, a portion of the flexible display 1110 may be rolled. For example, a portion 1111 of the flexible display 1110 may be rolled in a lower portion 1101 of the second housing part 1120 toward a rear side 1122 of the second housing part 1120. For example, a portion of the flexible display 1110 joined with a support member may be rolled toward the rear side 1122 of the second housing part 1120 along a rail.

According to an embodiment, one end 1102 of the flexible display 1110 may move along a lengthwise direction of the second housing part 1120. For example, when the electronic device is in a first state, the one end 1102 of the flexible display 1110 may move away from a lower end 1121 of the second housing part 1120 along the lengthwise direction of the second housing part 1120. For example, when the electronic device is in the second state, the one end 1102 of the flexible display 1110 may move close to the lower end 1121 of the second housing part 1120 along the lengthwise direction of the second housing part 1120. For example, the one end 1102 of the flexible display 1110 may move close to the rear side 1122 of the second housing part 1120. For example, the one end 1102 of the flexible display 1110 may move parallel with the second housing part 1120 in a state of maintaining a specific distance to the rear side 1122 of the second housing part 1120.

According to an embodiment, the one end 1102 of the flexible display 1110 may include a conductive coupling member 1130. For example, the conductive coupling member 1130 may be grounded with the flexible display 1110. That is, the conductive coupling member 1130 may have no voltage difference with respect to the flexible display 1110, or may have a very slight difference. For example, the conductive coupling member 1130 may be welded to one end of the flexible display 1110. For example, the conductive coupling member 1130 may be constructed of a conductive material. For example, the conductive coupling member 1130 may be plated with the conductive material.

According to an embodiment, the conductive coupling member 1130 may extend toward the rear side 1122 of the second housing part 1120. For example, the conductive coupling member 1130 may extend toward the rear side 1122 of the second housing part 1120 so as to be in contact with a portion of the rear side 1122 of the second housing part 1120. For example, the conductive coupling member 1130 may include a clip extending toward the rear side 1122 of the second housing part 1120. For example, the conductive coupling member 1130 may be a c-clip. That is, the conductive coupling member 1130 may be constructed in a ‘C’ shape so that a portion in a center is in contact with the rear side 1122 of the second housing part 1120. For example, the other end of the conductive coupling member 1130 may be bent toward the rear side 1122 of the second housing part 1120, and a portion in a center thereof may be bent toward the flexible display. For example, a portion in a center of the conductive coupling member 1130 may protrude toward the rear side 1122 of the second housing part 1120.

According to an embodiment, the conductive coupling member 1130 may be in contact with the second housing part 1120 of the electronic device. For example, the conductive coupling member 1130 extending toward the rear side 1122 of the second housing part 1120 may be in contact with the second housing part 1120. A portion in a center of the conductive coupling member 1130 protruding toward the rear side 1122 of the second housing part 1120 may be in contact with the second housing part 1120. For example, when the electronic device is in the first state and/or the second state, the conductive coupling member 1130 may be in contact with the second housing part 1120. For example, the conductive coupling member 1130 may be in contact with a contact portion disposed to the rear side 1122 of the second housing part 1120. For example, the contact portion may be constructed of a conductive material. For example, the contact portion may be plated with the conductive material.

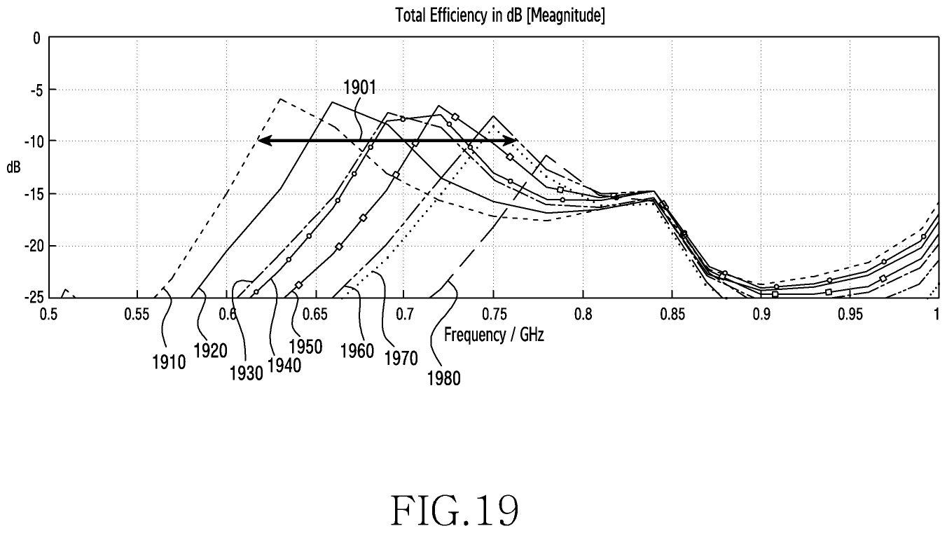

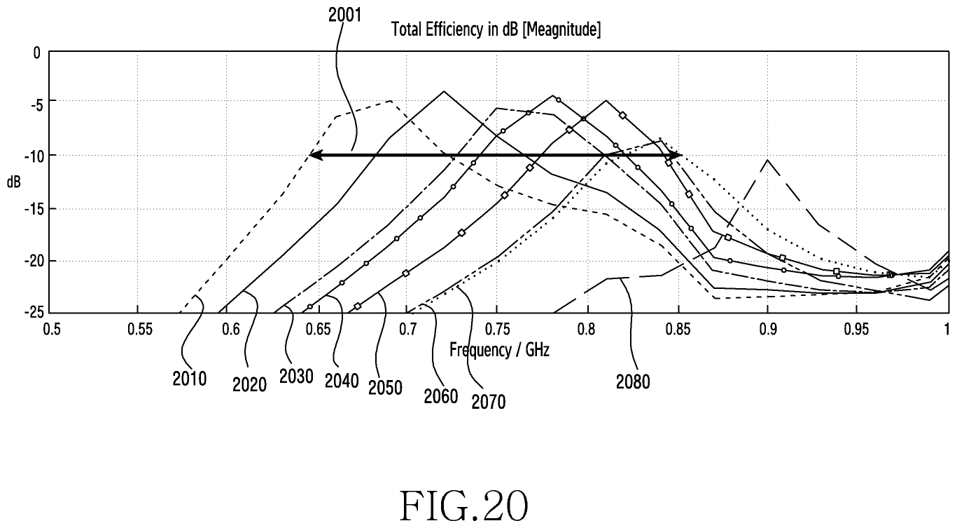

According to an embodiment, at least a portion of the conductive coupling member 1130 is in contact with the rear part 1122 of the second housing part 1120, and thus the flexible display 1110 may be grounded to the second housing part 1120. When the electronic device is in the second state, the flexible display 1110 is grounded to the second housing part 1120, and thus a resonance frequency of an antenna may be high-shifted as described below with reference to FIGS. 19 and 20.

According to an embodiment, at least a portion of the conductive coupling member 1130 may be electrically coupled to the second housing part 1120, only when the electronic device is in the second state. For example, at least the portion of the conductive coupling member 1130 may be in contact with a contact portion grounded with the second housing part 1120 only when the electronic device is in the second state. For example, the contact portion may be disposed to a region corresponding to a position of the conductive coupling member 1130, when the electronic device is in the second state.

According to the disclosed embodiment, the conductive coupling member 1130 constructed in a ‘C’ shape may be stably grounded to the second housing part 1120 even when there is a tolerance which occurs in a process of producing the electronic device 1100. In the conductive coupling member 1130 of which the other end is bent toward the rear side 1122 of the second housing part 1120 and a portion in a center thereof is bent toward the flexible display, a portion in a center, protruding toward the rear side 1122 of the second housing 1120, may be stably grounded to the rear side 1122 of the second housing part 1120. The conductive coupling member 1130 of the disclosed embodiment has elasticity, so as to be stably grounded to the rear side 1122 of the second housing part 1120.

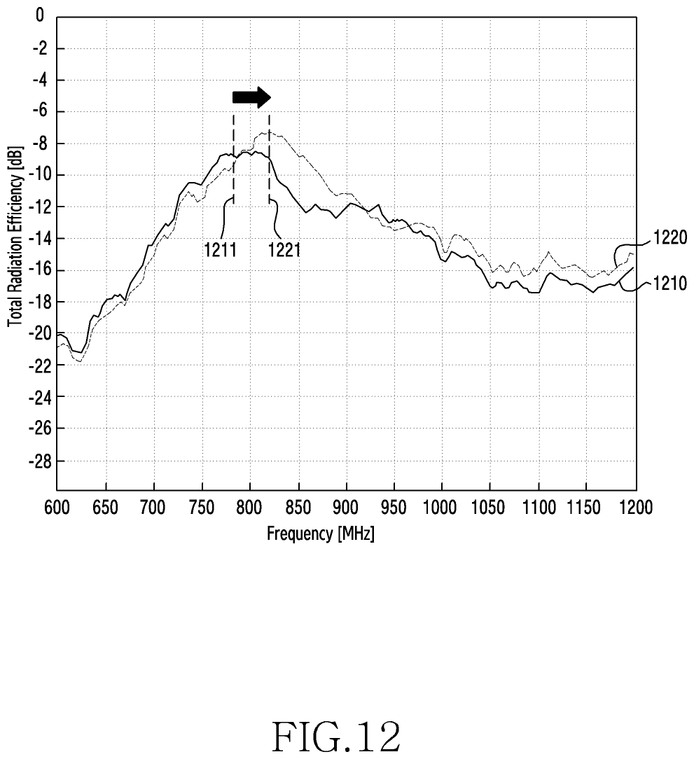

FIG. 12 is a drawing for comparative description of antenna performance depending on whether an electronic device has a conductive coupling member according to an embodiment of the disclosure.

Antenna performance of the electronic device 1000 described above with reference to FIG. 10 and antenna performance of the electronic device 1100 described above with reference to FIG. 11 are compared in the description of FIG. 12.

Referring to FIG. 12, a first graph 1210 illustrates antenna performance of the electronic device 1000 described above with reference to FIG. 10. Referring to the first graph 1210, a first resonance frequency 1211 of an antenna of the electronic device 1000 without a conductive coupling member may be about 780 MHz. Antenna efficiency at the first resonance frequency 1211 may be about −8.5 db.

Referring to FIG. 12, a second graph 1220 illustrates antenna performance of the electronic device 1100 described above with reference to FIG. 11. Referring to the second graph 1220, a second resonance frequency 1221 of an antenna of the electronic device 1000 without a conductive coupling member may be about 820 MHz. Antenna efficiency at the second resonance frequency 1221 may be about −7 db.

Comparing the first graph 1210 and the second graph 1220, it is confirmed that the resonance frequency is high-shifted from about 780 MHz to about 820 MHz in case of the antenna of the electronic device 1100 described above with reference to FIG. 11, compared to the antenna of the electronic device 1000 described above with reference to FIG. 10. In addition, it is confirmed that efficiency is improved from about −8.5 db to about −7 db in case of the antenna of the electronic device 1100 described above with reference to FIG. 11, compared to the antenna of the electronic device 1000 described above with reference to FIG. 10. Therefore, it is confirmed that the flexible display 1110 is electrically coupled to a second housing part (e.g., 1120 of FIG. 11) by means of a conductive coupling member (e.g., 1130 of FIG. 11), and thus the resonance frequency is high-shifted and the antenna performance is improved

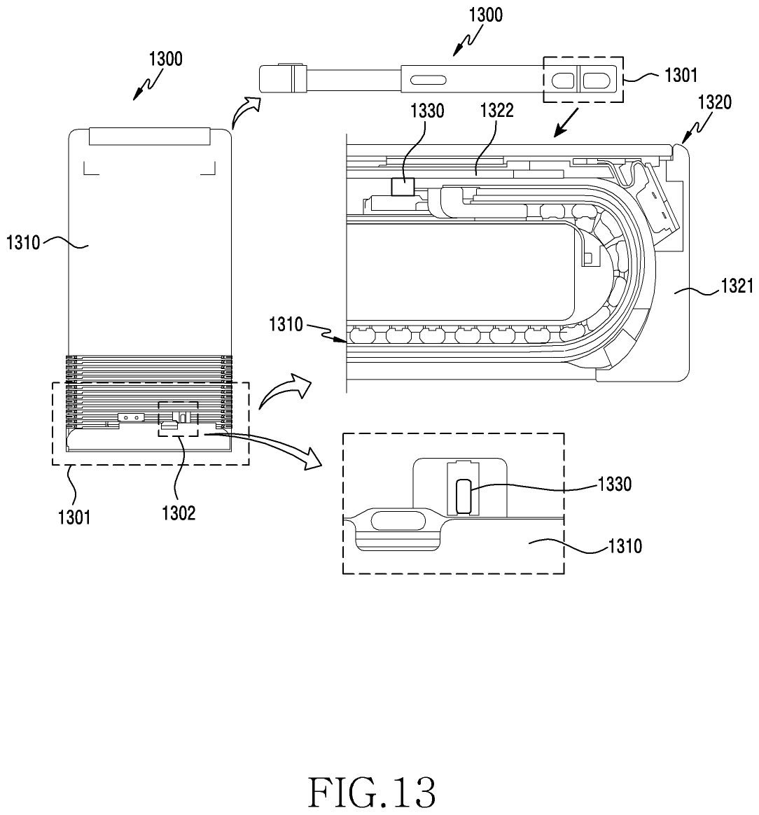

FIG. 13 is a drawing for explaining a conductive coupling member of an electronic device according to an embodiment of the disclosure.

The electronic device of FIG. 13 and parts constituting the electronic device may correspond respectively to the electronic device 101 described above with reference to FIGS. 1, 2A to 2D, 3A, 3B, 4A, and 4B and parts constituting the electronic device 101.

Referring to FIG. 13, a flexible display 1310 may be drawn into a second housing part 1320. For example, even if an electronic device 1300 of which a first housing part is drawn out from the second housing part 1320 is in a second state, a portion of the flexible display 1310 may be drawn into the second housing part 1320.

According to an embodiment, a portion of the flexible display 1310 may be rolled. For example, a portion 1311 of the flexible display 1310 may be rolled in a lower portion 1301 of the second housing part 1320 toward a rear side 1322 of the second housing part 1320. For example, a portion of the flexible display 1310 joined with a support member may be rolled toward the rear side 1322 of the second housing part 1320 along a rail.

According to an embodiment, one end 1302 of the flexible display 1310 may move along a lengthwise direction of the second housing part 1320. For example, when the electronic device is in a first state, the one end 1302 of the flexible display 1310 may move away from a lower end 1321 of the second housing part 1320 along the lengthwise direction of the second housing part 1320. For example, when the electronic device is in the second state, the one end 1302 of the flexible display 1310 may move close to the lower end 1321 of the second housing part 1320 along the lengthwise direction of the second housing part 1320. For example, the one end 1302 of the flexible display 1310 may move close to the rear side 1322 of the second housing part 1320. For example, one end of the flexible display 1310 may move parallel with the second housing part 1320 in a state of maintaining a specific distance to the rear side 1322 of the second housing part 1320.

According to an embodiment, the one end 1302 of the flexible display 1310 may include a conductive coupling member 1330. For example, the conductive coupling member 1330 may be grounded with the flexible display 1310. That is, the conductive coupling member 1330 may have no voltage difference with respect to the flexible display 1310, or may have a very slight difference. For example, the conductive coupling member 1330 may be welded to one end of the flexible display 1310. For example, the conductive coupling member 1330 may be constructed of a conductive material. For example, the conductive coupling member 1330 may be plated with the conductive material.

According to an embodiment, the conductive coupling member 1330 may extend toward the rear side 1322 of the second hosing part 1320. For example, the conductive coupling member 1330 may include a column extending toward the rear side 1322 of the second housing part 1320 for surface contact with the rear side 1322 of the second housing part 1320. For example, the conductive coupling member 1330 may include a horn extending toward the rear side 1322 of the second housing part 1320 for point contact with the rear side 1322 of the second housing part 1320. For example, the conductive coupling member 1330 may include a rake extending toward the rear side 1322 of the second housing part 1320 for multi-point contact with the rear side 1322 of the second housing part 1320.

According to an embodiment, the conductive coupling member 1330 may be in contact with the second housing part 1320 of the electronic device. For example, the conductive coupling member 1330 extending toward the rear side 1322 of the second housing part 1320 may be in contact with the second housing part 1320. For example, when the electronic device is in the first state and/or the second state, the conductive coupling member 1330 may be in contact with the second housing part 1320. For example, the conductive coupling member 1330 may be in contact with a contact portion disposed to the rear side 1322 of the second housing part 1320. For example, the contact portion may be constructed of a conductive material. For example, the contact portion may be plated with the conductive material.

According to an embodiment, at least a portion of the conductive coupling member 1330 is in contact with the rear side 1322 of the second housing part 1320, and thus the flexible display 1310 may be grounded to the second housing part 1320. When the electronic device is in the second state, the flexible display 1310 is grounded to the second housing part 1320, and thus a resonance frequency of an antenna may be high-shifted as described below with reference to FIGS. 19 and 20.

According to an embodiment, at least a portion of the conductive coupling member 1330 may be electrically coupled to the second housing part 1320, only when the electronic device is in the second state. For example, at least the portion of the conductive coupling member 1330 may be in contact with a contact portion grounded with the second housing part 1320 only when the electronic device is in the second state. For example, the contact portion may be disposed to a region corresponding to a position of the conductive coupling member 1330, when the electronic device is in the second state.

According to the disclosed embodiment, the conductive coupling member 1330 may be stably grounded to the second housing part 1320. The conductive coupling member 1330 may ensure a wide ground region.

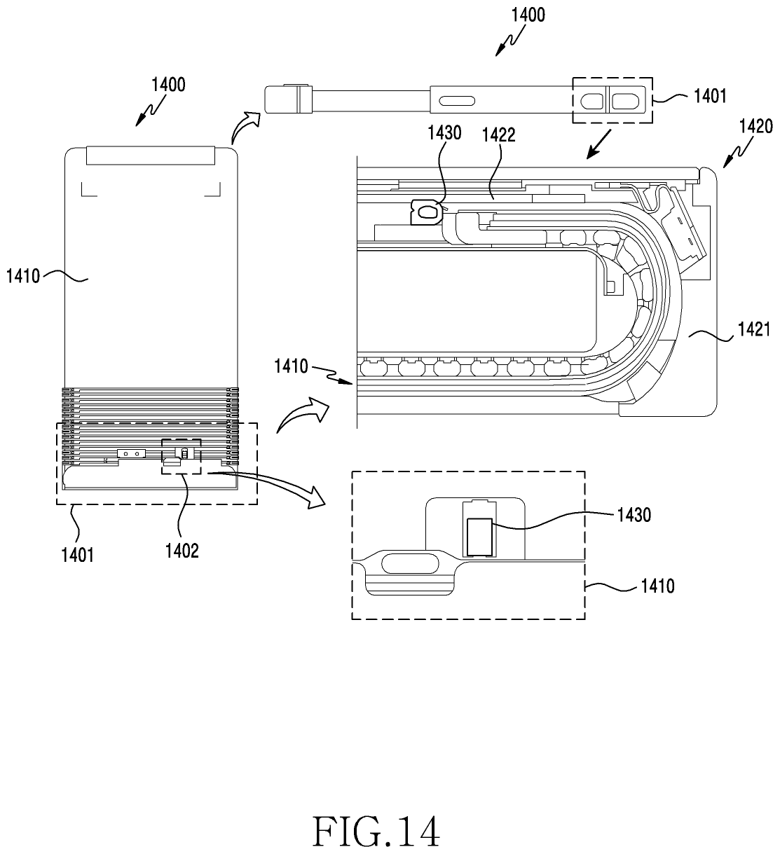

FIG. 14 is a drawing for explaining a conductive coupling member of an electronic device according to an embodiment of the disclosure.

The electronic device of FIG. 14 and parts constituting the electronic device may correspond respectively to the electronic device 101 described above with reference to FIGS. 1, 2A to 2D, 3A, 3B, 4A, and 4B and parts constituting the electronic device 101.

Referring to FIG. 14, a flexible display 1410 may be drawn into a second housing part 1420. For example, even if an electronic device 1400 of which a first housing part is drawn out from the second housing part 1420 is in a second state, a portion of the flexible display 1410 may be drawn into the second housing part 1420.

According to an embodiment, a portion of the flexible display 1410 may be rolled. For example, a portion 1411 of the flexible display 1410 may be rolled in a lower portion 1401 of the second housing part 1420 toward a rear side 1422 of the second housing part 1420. For example, a portion of the flexible display 1410 joined with a support member may be rolled toward the rear side 1422 of the second housing part 1420 along a rail.

According to an embodiment, one end 1402 of the flexible display 1410 may move along a lengthwise direction of the second housing part 1420. For example, when the electronic device is in a first state, the one end 1402 of the flexible display 1410 may move away from a lower end 1421 of the second housing part 1420 along the lengthwise direction of the second housing part 1420. For example, when the electronic device is in the second state, the one end 1402 of the flexible display 1410 may move close to the lower end 1421 of the second housing part 1420 along the lengthwise direction of the second housing part 1420. For example, the one end 1402 of the flexible display 1410 may move close to the rear side 1422 of the second housing part 1420. For example, one end of the flexible display 1410 may move parallel with the second housing part 1420 in a state of maintaining a specific distance to the rear side 1422 of the second housing part 1420.

According to an embodiment, the one end 1402 of the flexible display 1410 may include a conductive coupling member 1430. For example, the conductive coupling member 1430 may be grounded with the flexible display 1410. That is, the conductive coupling member 1430 may have no voltage difference with respect to the flexible display 1410, or may have a very slight difference. For example, the conductive coupling member 1430 may be attached to the one end 1402 of the flexible display 1410. For example, the conductive coupling member 1430 may be constructed of a conductive material. For example, the conductive coupling member 1430 may be plated with the conductive material. For example, a surface of the conductive coupling member 1430 may be surrounded at least in part by a conductive material. For example, the conductive coupling member 1430 may be an elastic body. For example, the conductive coupling member 1430 may be a porous material constructed of a synthetic resin. For example, the conductive coupling member 1430 may be constructed in a columnar shape. For example, the conductive coupling member 1430 may include an opening in a center.

According to an embodiment, the conductive coupling member 1430 may be in contact with the second housing part 1420 of the electronic device. For example, the conductive coupling member 1430 extending toward the rear side 1422 of the second housing part 1420 may be in contact with the second housing part 1420. For example, a conductive material surrounding the conductive coupling member 1430 may be in contact with the second housing part 1420. For example, when the electronic device is in the first state and/or the second state, the conductive coupling member 1430 may be in contact with the second housing part 1420. For example, the conductive coupling member 1430 may be in contact with a contact portion disposed to the rear side 1422 of the second housing part 1420. For example, the contact portion may be constructed of a conductive material. For example, the contact portion may be plated with the conductive material.

According to an embodiment, at least a portion of the conductive coupling member 1430 is in contact with the rear part 1422 of the second housing part 1420, and thus the flexible display 1410 may be grounded to the second housing part 1420. When the electronic device is in the second state, the flexible display 1410 is grounded to the second housing part 1420, and thus a resonance frequency of an antenna may be high-shifted as described below with reference to FIGS. 19 and 20.

According to an embodiment, at least a portion of the conductive coupling member 1430 may be electrically coupled to the second housing part 1420, only when the electronic device is in the second state. For example, at least the portion of the conductive coupling member 1430 may be in contact with a contact portion grounded with the second housing part 1420 only when the electronic device is in the second state. For example, the contact portion may be disposed to a region corresponding to a position of the conductive coupling member 1430, when the electronic device is in the second state.

According to the disclosed embodiment, the conductive coupling member 1430 may be stably grounded to the second housing part 1420. The conductive coupling member 1430 may ensure a wide ground region. According to the disclosed embodiment, when the second housing part 1420 moves, noise and scratches caused by friction with the conductive coupling member may not occur.

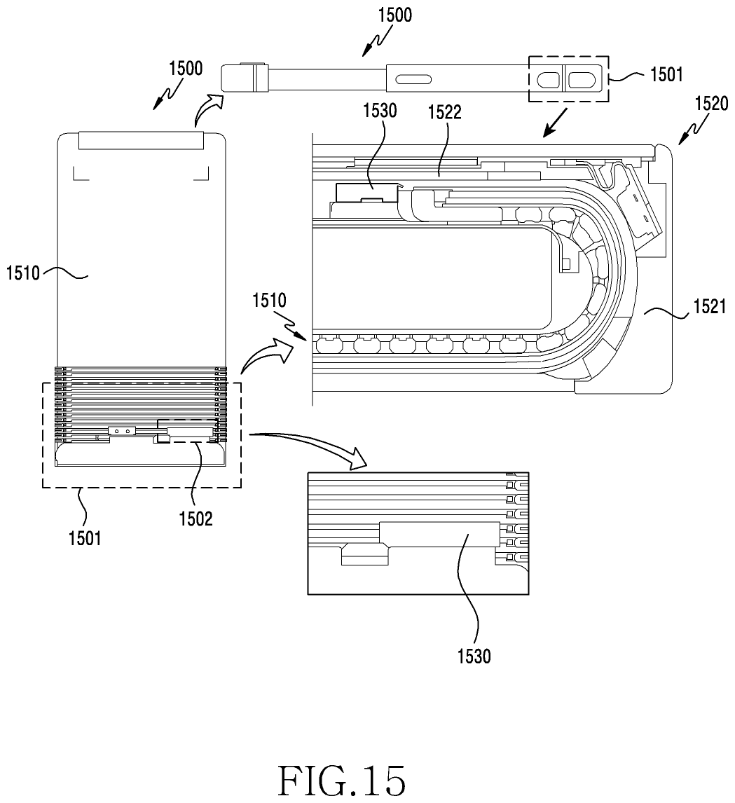

FIG. 15 is a drawing for explaining a conductive coupling member of an electronic device according to an embodiment of the disclosure.

The electronic device of FIG. 15 and parts constituting the electronic device may respectively correspond to the electronic device 101 described above with reference to FIGS. 1, 2A to 2D, 3A, 3B, 4A, and 4B and parts constituting the electronic device 101.

Referring to FIG. 15, a flexible display 1510 may be drawn into a second housing part 1520. For example, even if an electronic device 1500 of which a first housing part is drawn out from the second housing part 1520 is in a second state, a portion of the flexible display 1510 may be drawn into the second housing part 1520.

According to an embodiment, a portion of the flexible display 1510 may be rolled. For example, a portion 1511 of the flexible display 1510 may be rolled in a lower portion 1501 of the second housing part 1520 toward a rear side 1522 of the second housing part 1520. For example, a portion of the flexible display 1510 joined with a support member may be rolled toward the rear side 1522 of the second housing part 1520 along a rail.

According to an embodiment, one end 1502 of the flexible display 1510 may move along a lengthwise direction of the second housing part 1520. For example, when the electronic device is in a first state, the one end 1502 of the flexible display 1510 may move away from a lower end 1521 of the second housing part 1520 along the lengthwise direction of the second housing part 1520. For example, when the electronic device is in the second state, the one end 1502 of the flexible display 1510 may move close to the lower end 1521 of the second housing part 1520 along the lengthwise direction of the second housing part 1520. For example, the one end 1502 of the flexible display 1510 may move close to the rear side 1522 of the second housing part 1520. For example, the one end 1502 of the flexible display 1510 may move parallel with the second housing part 1520 in a state of maintaining a specific distance to the rear side 1522 of the second housing part 1520.

According to an embodiment, the one end 1502 of the flexible display 1510 may include a conductive coupling member 1530. For example, the conductive coupling member 1530 may be grounded with the flexible display 1510. That is, the conductive coupling member 1530 may have no voltage difference with respect to the flexible display 1510, or may have a very slight difference. For example, the conductive coupling member 1530 may be welded to one end of the flexible display 1510. For example, the conductive coupling member 1530 may extend toward the rear side 1522 of the second housing part 1520 to have a specific distance or less to the rear side 1522 of the second housing part 1520. For example, the conductive coupling member 1530 may include a plate disposed to be parallel with the rear side 1522 of the second housing part 1520. For example, the conductive coupling member 1530 may be constructed of a conductive material. For example, the conductive coupling member 1530 may be plated with the conductive material. For example, a surface of the conductive coupling member 1330 may be surrounded at least in part by a conductive material. For example, the plate may be constructed of a metal material. For example, a surface of the plate may be plated with the conductive material.

According to an embodiment, the conductive coupling member 1530 may be electrically coupled with the second housing part 1520 of the electronic device. For example, the plate of the conductive coupling member 1530 may be in contact with the rear side 1522 of the second housing part 1520. For example, the conductive coupling member 1530 may be coupled with the rear side 1522 of the second housing part 1520. For example, the conductive coupling member 1530 may be coupled with a conductive plate disposed to the rear side 1522 of the second housing part 1520.

According to an embodiment, at least a portion of the conductive coupling member 1530 is coupled with the rear part 1522 of the second housing part 1520, and thus the flexible display 1510 may be grounded to the second housing part 1520. When the electronic device is in the second state, the flexible display 1510 is grounded to the second housing part 1520, and thus a resonance frequency of an antenna may be high-shifted as described below with reference to FIGS. 19 and 20.

According to the disclosed embodiment, there may be no friction in the conductive coupling member 1530, when the second housing part 1520 moves with respect to the first housing part. According to the disclosed embodiment, when the second housing part 1520 moves, noise and scratches caused by the friction with the conductive coupling member may not occur.

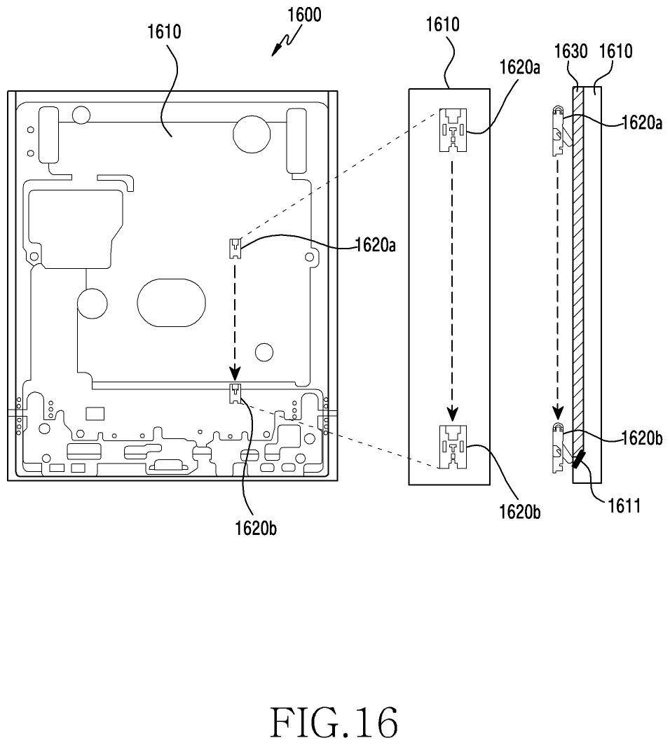

FIG. 16 is a drawing for explaining a second housing part with which a conductive coupling member of an electronic device is in contact according to an embodiment of the disclosure.

An electronic device 1600 of FIG. 16 and parts constituting the electronic device 1600 may respectively correspond to the electronic device 101 described above with reference to FIGS. 1, 2A to 2D, 3A, 3B, 4A, and 4B and parts constituting the electronic device 101.

Referring to FIG. 16, according to an embodiment, a second housing part 1610 may move in accordance with a state of an electronic device 1600. For example, the second housing part 1610 may move between a retracted position and an extended position in accordance with the state of the electronic device 1600.

According to an embodiment, the second housing part 1610 may include a recess 1630 along a path of conductive coupling members 1620a and 1620b which move in accordance with the state of the electronic device 1600. For example, the recess 1630 may be a region extending from a first region to a second region. The first region may be a region corresponding to a first position of the conductive coupling member 1620a when the electronic device 1600 is in the first state. The second region may be a region corresponding to a second position of the conductive coupling member 1620b when the electronic device 1600 is in the second state. For example, the recess 1630 may be a region recessed from the first region to the second region so that the second housing part 1610 decreases in thickness. For example, the recess 1630 may be a region in which the second housing part 1610 is not in contact with the conductive coupling members 1620a and 1620b.

According to an embodiment, the second housing part 1610 may be in contact with the conductive coupling members 1620a and 1620b. For example, the second housing part 1610 may move in accordance with the state of the electronic device 1600, so as to be in contact with the conductive coupling members 1620a and 1620b in at least one region. For example, the second housing part 1610 may be in contact with the conductive coupling member 1620a in a first region, when the electronic device is in the first state. For example, the second housing part 1610 may be in contact with the conductive coupling member 1620b in the second region, when the electronic device is in the second state. For example, the second housing part 1610 may be in contact with the conductive coupling members 1620a and 1620b, so as to be grounded with the flexible display.

According to an embodiment, the second housing part 1610 may include a contact portion 1611. For example, the contact portion 1611 may be a member for electrically coupling the conductive coupling members 1620a and 1620b and the second housing part 1610. For example, the contact portion 1611 may be constructed of a conductive material. For example, the contact portion 1611 may be plated with the conductive material. For example, the contact portion 1611 may be disposed to a region corresponding to positions of the conductive coupling members 1620a and 1620b. For example, when the electronic device 1600 is in the second state, the contact portion 1611 may be disposed to a region corresponding to the position of the conductive coupling member 1620b. For example, the contact portion 1611 may be disposed to a region corresponding to the position of the conductive coupling member 1620b in a state where the second housing part 1610 moves to an extended position.

According to the disclosed embodiment, the second housing part 1610 may be selectively in contact with the conductive coupling members 1620a and 1620b through the recess 1630 and the contact portion 1611. For example, the second housing part 1610 may be in contact with the conductive coupling member 1620b only in the second region through the recess 1630 and the contact portion 1611.

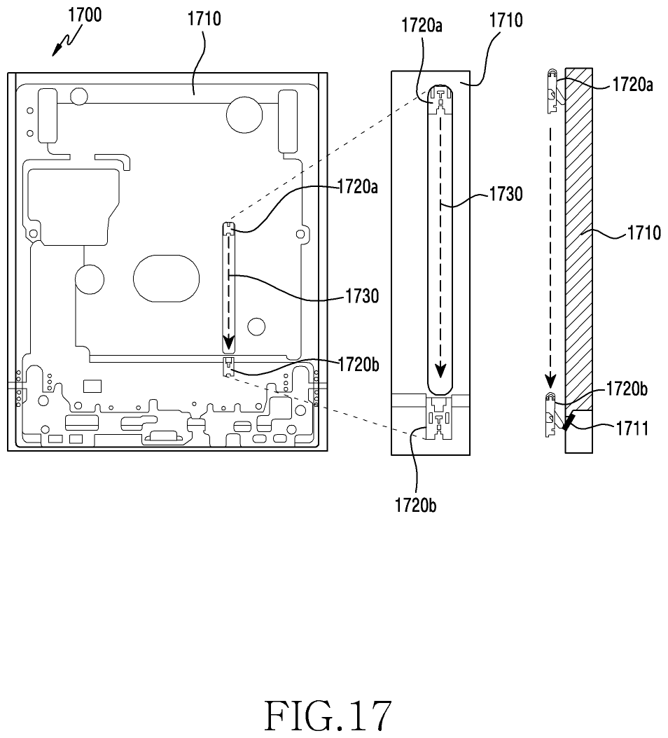

FIG. 17 is a drawing for explaining a second housing part with which a conductive coupling member of an electronic device is in contact according to an embodiment of the disclosure.

The electronic device of FIG. 17 and parts constituting the electronic device may correspond respectively to the electronic device 101 described above with reference to FIGS. 1, 2A to 2D, 3A, 3B, 4A, and 4B and parts constituting the electronic device 101.

Referring to FIG. 17, according to an embodiment, a second housing part 1710 may move in accordance with a state of an electronic device 1700. For example, the second housing part 1710 may move between a retracted position and an extended position in accordance with the state of the electronic device 1700.

According to an embodiment, the second housing part 1710 may include a slit 1730 along a path of conductive coupling members 1720a and 1720b which move in accordance with the state of the electronic device 1700. For example, the slit 1730 may be a region extending from a first region to a second region. The first region may be a region corresponding to a first position of the conductive coupling member 1720a when the electronic device 1700 is in the first state. The second region may be a region corresponding to a second position of the conductive coupling member 1720b when the electronic device 1700 is in the second state. For example, the slit 1730 may include an opening constructed at the second housing part 1710 from the first region to the second region. For example, the slit 1730 may be a region in which the second housing part 1710 is not in contact with the conductive coupling members 1720a and 1720b.

According to an embodiment, the second housing part 1710 may be in contact with the conductive coupling members 1720a and 1720b. For example, the second housing part 1710 may move in accordance with the state of the electronic device 1700, so as to be in contact with the conductive coupling members 1720a and 1720b in at least one region. For example, the second housing part 1710 may be in contact with the conductive coupling member 1720a in a first region, when the electronic device is in the first state. For example, the second housing part 1710 may be in contact with the conductive coupling member 1720b in the second region, when the electronic device is in the second state. For example, the second housing part 1710 may be in contact with the conductive coupling members 1720a and 1720b, so as to be grounded with the flexible display.

According to an embodiment, the second housing part 1710 may include a contact portion 1711. For example, the contact portion 1711 may be a member for electrically coupling the conductive coupling members 1720a and 1720b and the second housing part 1710. For example, the contact portion 1711 may be constructed of a conductive material. For example, the contact portion 1711 may be plated with the conductive material. For example, the contact portion 1711 may be disposed to a region corresponding to positions of the conductive coupling members 1720a and 1720b. For example, when the electronic device 1700 is in the second state, the contact portion 1711 may be disposed to a region corresponding to the position of the conductive coupling member 1720b. For example, the contact portion 1711 may be disposed to a region corresponding to the position of the conductive coupling member 1720b in a state where the second housing part 1710 moves to an extended position.

According to the disclosed embodiment, the second housing part 1710 may be selectively in contact with the conductive coupling members 1720a and 1720b through the slit 1730 and the contact portion 1711. For example, the second housing part 1710 may be in contact with the conductive coupling member 1720b only in the second region through the slit 1730 and the contact portion 1711.

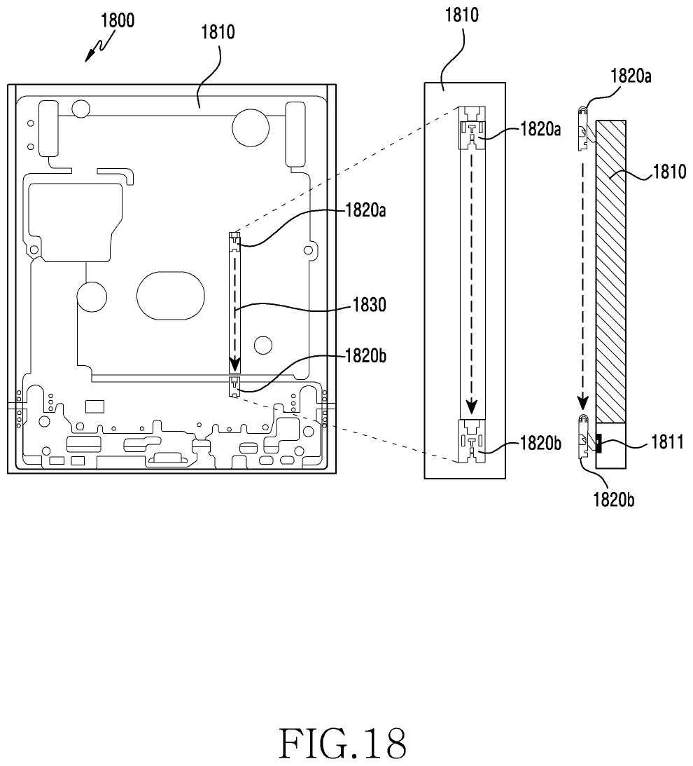

FIG. 18 is a drawing for explaining a second housing part with which a conductive coupling member of an electronic device is in contact according to an embodiment of the disclosure.

The electronic device of FIG. 18 and parts constituting the electronic device may respectively correspond to the electronic device 101 described above with reference to FIGS. 1, 2A to 2D, 3A, 3B, 4A, and 4B and parts constituting the electronic device 101.

Referring to FIG. 18, according to an embodiment, a second housing part 1810 may move in accordance with a state of an electronic device 1800. For example, the second housing part 1810 may move between a retracted position and an extended position in accordance with the state of the electronic device 1800.

According to an embodiment, the second housing part 1810 may include a slit 1830 along a path of conductive coupling members 1820a and 1820b which move in accordance with the state of the electronic device 1800. For example, the slit 1830 may be a region extending from a first region to a second region. The first region may be a region corresponding to a first position of the conductive coupling member 1820a when the electronic device 1800 is in the first state. The second region may be a region corresponding to a second position of the conductive coupling member 1820b when the electronic device 1800 is in the second state. For example, the slit 1830 may include an opening constructed at the second housing part 1810 from the first region to the second region.

According to an embodiment, the second housing part 1810 may be in contact with the conductive coupling members 1820a and 1820b. For example, the second housing part 1810 may move in accordance with the state of the electronic device 1800, so as to be in contact with the conductive coupling members 1820a and 1820b in at least one region. For example, the second housing part 1810 may be in contact with the conductive coupling member 1820a in a first region, when the electronic device is in the first state. For example, the second housing part 1810 may be in contact with the conductive coupling member 1820b in the second region, when the electronic device is in the second state. For example, the second housing part 1810 may be in contact with the conductive coupling members 1820a and 1820b, so as to be grounded with the flexible display.

According to an embodiment, the slit 1830 may be filled with a non-conductive material. For example, the slit 1830 may be filled with a synthetic resin. For example, since the slit 1830 is filled with the non-conductive material, the flexible display and the second housing part 1810 may not be grounded even when the non-conductive material is in contact with the conductive coupling members 1820a and 1820b.

According to an embodiment, the second housing part 1810 may include a contact portion 1811. For example, the contact portion 1811 may be a member for electrically coupling the conductive coupling members 1820a and 1820b and the second housing part 1810. For example, the contact portion 1811 may be constructed of a conductive material. For example, the contact portion 1811 may be plated with the conductive material. For example, the contact portion 1811 may be disposed to a region corresponding to positions of the conductive coupling members 1820a and 1820b. For example, when the electronic device 1800 is in the second state, the contact portion 1811 may be disposed to a region corresponding to the position of the conductive coupling member 1820b. For example, the contact portion 1811 may be disposed to a region corresponding to the position of the conductive coupling member 1820b in a state where the second housing part 1810 moves to an extended position.

According to the disclosed embodiment, the second housing part 1810 may be selectively in contact with the conductive coupling members 1820a and 1820b through the contact portion 1811 and a non-conductive material filled in the slit 1830. For example, the second housing part 1810 may be in contact with the conductive coupling member 1820b only in the second region through the contact portion 1811 and the non-conductive material filled in the slit 1830.

FIG. 19 is a drawing for explaining performance of an antenna of which an element is coupled to a conductive member through the first switching module 521 and second switching module 522 of FIG. 5, when a conductive coupling member of an electronic device in a second state is not in contact with a second housing part, according to an embodiment of the disclosure.

Referring to FIG. 19, a first graph 1910 illustrates per-frequency efficiency of an antenna, when only an inductive element of 20 nH is joined to a conductive member through a first switching module. Referring to the first graph 1910, the antenna may show high efficiency at a frequency band of about 630 MHz.

Referring to FIG. 19, a second graph 1920 illustrates per-frequency efficiency of an antenna, when only an inductive element of 10 nH is joined to a conductive member through a first switching module. Referring to the second graph 1920, the antenna may show high efficiency at a frequency band of about 660 MHz.

Referring to FIG. 19, a third graph 1930 illustrates per-frequency efficiency of an antenna, when only an inductive element of 5 nH is joined to a conductive member through a first switching module. Referring to the third graph 1930, the antenna may show high efficiency at a frequency band of about 690 MHz.

Referring to FIG. 19, a fourth graph 1940 illustrates per-frequency efficiency of an antenna, when an inductive element of 20 nH is joined to a conductive member through a first switching module and an element for impedance matching is joined to the conductive member through a second switching module. Referring to the fourth graph 1940, the antenna may show high efficiency at a frequency band of about 720 MHz.

Referring to FIG. 19, a fifth graph 1950 illustrates per-frequency efficiency of an antenna, when an inductive element of 10 nH is joined to a conductive member through a first switching module and an element for impedance matching is joined to the conductive member through a second switching module. Referring to the fifth graph 1950, the antenna may show high efficiency at a frequency band of about 720 MHz.

Referring to FIG. 19, a sixth graph 1960 illustrates per-frequency efficiency of an antenna, when an inductive element of 5 nH is joined to a conductive member through a first switching module and an element for impedance matching is joined to the conductive member through a second switching module. Referring to the sixth graph 1960, the antenna may show high efficiency at a frequency band of about 750 MHz.

Referring to FIG. 19, a seventh graph 1970 illustrates per-frequency efficiency of an antenna, when only an inductive element of 1 nH is joined to a conductive member through a first switching module. Referring to the seventh graph 1970, the antenna may show high efficiency at a frequency band of about 750 MHz.

Referring to FIG. 19, an eighth graph 1980 illustrates per-frequency efficiency of an antenna, when an inductive element of 1 nH is joined to a conductive member through a first switching module and an element for impedance matching is joined to the conductive member through a second switching module. Referring to the eighth graph 1980, the antenna may show high efficiency at a frequency band of about 770 MHz. In this case, however, it is difficult for the antenna to transmit and receive a signal with efficiency of about −12 dB.

Referring to the first graph 1910 to the eighth graph 1980, the electronic device (e.g., 600a of FIG. 6) in the second state may couple at least one element to the conductive member by using the first switching module and the second switching module, thereby transmitting and receiving a signal by using a frequency bandwidth 1901 between about 630 MHz and about 750 MHz. Even in a case where the electronic device (e.g., 600b of FIG. 6) in the second state couples the at least one element to the conductive member by using the first switching module and the second switching module, it may be difficult to transmit and receive a signal by using a frequency band of about 800 MHz to about 960 MHz. Accordingly, it may be difficult for the electronic device in the second state to use a wireless communication service using the frequency band of about 800 MHz to about 960 MHz.

FIG. 20 is a drawing for explaining performance of an antenna of which an element is coupled to a conductive member through the first switching module 521 and second switching module 522 of FIG. 5, when a conductive coupling member of an electronic device in a second state is in contact with a second housing part, according to an embodiment of the disclosure.

Referring to FIG. 20, a first graph 2010 illustrates per-frequency efficiency of an antenna, when only an inductive element of 20 nH is joined to a conductive member through a first switching module. Referring to the first graph 2010, the antenna may show high efficiency at a frequency band of about 690 MHz.

Referring to FIG. 20, a second graph 2020 illustrates per-frequency efficiency of an antenna, when only an inductive element of 10 nH is joined to a conductive member through a first switching module. Referring to the second graph 2020, the antenna may show high efficiency at a frequency band of about 720 MHz.

Referring to FIG. 20, a third graph 2030 illustrates per-frequency efficiency of an antenna, when only an inductive element of 5 nH is joined to a conductive member through a first switching module. Referring to the third graph 2030, the antenna may show high efficiency at a frequency band of about 750 MHz.

Referring to FIG. 20, a fourth graph 2040 illustrates per-frequency efficiency of an antenna, when an inductive element of 20 nH is joined to a conductive member through a first switching module and an element for impedance matching is joined to the conductive member through a second switching module. Referring to the fourth graph 2040, the antenna may show high efficiency at a frequency band of about 780 MHz.

Referring to FIG. 20, a fifth graph 2050 illustrates per-frequency efficiency of an antenna, when an inductive element of 10 nH is joined to a conductive member through a first switching module and an element for impedance matching is joined to the conductive member through a second switching module. Referring to the fifth graph 2050, the antenna may show high efficiency at a frequency band of about 810 MHz.

Referring to FIG. 20, a sixth graph 2060 illustrates per-frequency efficiency of an antenna, when an inductive element of 5 nH is joined to a conductive member through a first switching module and an element for impedance matching is joined to the conductive member through a second switching module. Referring to the sixth graph 2060, the antenna may show high efficiency at a frequency band of about 840 MHz.

Referring to FIG. 20, a seventh graph 2070 illustrates per-frequency efficiency of an antenna, when only an inductive element of 1 nH is joined to a conductive member through a first switching module. Referring to the seventh graph 2070, the antenna may show high efficiency at a frequency band of about 840 MHz.

Referring to FIG. 20, an eighth graph 2080 illustrates per-frequency efficiency of an antenna, when an inductive element of 1 nH is joined to a conductive member through a first switching module and an element for impedance matching is joined to the conductive member through a second switching module. Referring to the eighth graph 2080, the antenna may show high efficiency at a frequency band of about 900 MHz. In this case, however, it is difficult for the antenna to transmit and receive a signal with efficiency of about −11 dB.

Referring to the first graph 2010 to the eighth graph 2080, the electronic device (e.g., 600a of FIG. 6) in the second state may couple at least one element to the conductive member by using the first switching module and the second switching module, thereby transmitting and receiving a signal at a frequency bandwidth 2001 between about 660 MHz and about 850 MHz.

Comparing FIGS. 19 and 20, in the electronic device in the second state, the flexible display is not grounded to the second housing part, and thus a resonance frequency of an antenna which transmits and receives a signal by using a conductive member disposed to a lower end of the second housing part may be low-shifted.

Comparing FIGS. 19 and 20, in the electronic device in the second state, a rear side of the second housing part is in contact with one end of the flexible display, and thus the resonance frequency of the antenna may be high-shifted. Since the rear side of the second housing part is in contact with the one end of the flexible display, unstable coupling between the second housing part and the flexible display becomes stable, and thus the resonance frequency of the antenna may be high-shifted.

Comparing FIGS. 19 and 20, in the electronic device in the second state, the rear side of the second housing part and the one end of the flexible display are in contact, and thus a bandwidth for transmitting and receiving a signal may be extended. Since the rear side of the second housing part and the one end of the flexible display are in contact, unstable coupling between the second housing part and the flexible display becomes stable, thereby extending the bandwidth. For example, the rear side of the second housing part and the one end of the flexible display are in contact, and thus the electronic device in the second state may transmit and receive a signal through a frequency bandwidth 2001 between about 660 MHz and about 850 MHz. However, when the rear side of the second housing part and the one end of the flexible display are not in contact, the electronic device in the second state may transmit and receive a signal through a frequency bandwidth 1901 between about 630 MHz and about 750 MHz. Accordingly, the rear side of the second housing part and the flexible display are grounded, and thus the electronic device (e.g., 600b of FIG. 6) in the second state may transmit and receive the signal by using the frequency band of about 750 MHz to about 850 MHz.

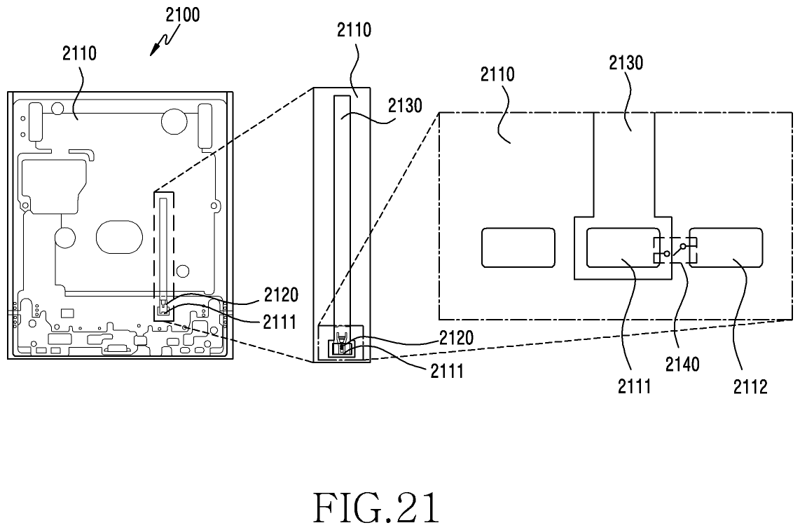

FIG. 21 is a drawing for explaining a second housing part with which a conductive coupling member of an electronic device is selectively in contact according to an embodiment of the disclosure.

An electronic device 2100 of FIG. 21 and parts constituting the electronic device 2100 may respectively correspond to the electronic device 101 described above with reference to FIGS. 1, 2A to 2D, 3A, 3B, 4A, and 4B and parts constituting the electronic device 101.

Referring to FIG. 21, according to an embodiment, a second housing part 2110 may move in accordance with a state of an electronic device 2100. For example, the second housing part 2110 may move between a retracted position and an extended position in accordance with the state of the electronic device 2100.

According to an embodiment, a conductive coupling member 2120 may move along a path 2130 in accordance with the state of the electronic device 2100. For example, the conductive coupling member 2120 may move between a first position and a second position along the path 2130. The first position may be a position of the conductive coupling member 2120 when the electronic device 2100 is in the first state. The second position may be a position of the conductive coupling member 2120 when the electronic device 2100 is in the second state.

According to an embodiment, the second housing part 2110 may be in contact with the conductive coupling member 2120. For example, the second housing part 2110 may move in accordance with the state of the electronic device 2100, so as to be in contact with the conductive coupling member 2120 in at least one region.

According to an embodiment, the second housing part 2110 may be selectively in contact with the conductive coupling member 2120. For example, the second housing part 2110 may be in contact with the conductive coupling member 2120 only in the second region. For example, the conductive coupling member 2120 may be in contact with a contact portion 2111 of the second housing part 2110 in the second region. For example, the path 2130 of the conductive coupling member 2120 may include the recess (e.g., 1630 of FIG. 16) described above with reference to FIG. 16, and thus the conductive coupling member 2120 may not be in contact with the second housing part 2110 between the first position and the second position. For example, the path 2130 of the conductive coupling member 2120 includes the slit (e.g., 1730 of FIG. 17) described above with reference to FIG. 17, and thus the conductive coupling member 2120 may not be in contact with the second housing part 2110 between the first position and the second position. For example, the path 2130 of the conductive coupling member 2120 includes the slit (e.g., 1830 of FIG. 18) filled with the non-conductive material described above with reference to FIG. 18, and thus the conductive coupling member 2120 may not be in contact with the second housing part 2110 between the first position and the second position.

According to an embodiment, the second housing part 2110 may include the contact portion 2111. For example, the contact portion 2111 may be a member for electrically coupling the conductive coupling member 2120 and the second housing part 2110. For example, the contact portion 2111 may be constructed of a conductive material. For example, the contact portion 2111 may be plated with the conductive material.

According to an embodiment, the contact portion 2111 may be selectively coupled with the second housing part 2110. For example, the contact portion 2111 may be separated from the second housing part 2110. For example, the contact portion 2111 may be coupled with the second housing part through a grounding portion 2112. For example, the grounding portion 2112 may include a region electrically coupled with the second housing part 2110. For example, the grounding portion 2112 may be constructed of a conductive material. For example, the grounding portion 2112 may be plated with the conductive material. For example, the grounding portion 2112 may be coupled with the contact portion 2111 through a switching module 2140.

According to the disclosed embodiment, the contact portion 2111 to be in contact with the conductive coupling member 2120 is coupled to the grounding portion through the switching module 2140, and thus the conductive coupling member 2120 may be selectively coupled to the second housing part 2110. According to the disclosed embodiment, the electronic device 2100 selectively couples the conductive coupling member 2120 with the second housing part 2110 through the switching module 2140, and thus an antenna disposed to a lower end of the electronic device 2100 may transmit and receive a signal by using a frequency of a wide band. For example, the electronic device 2100 does not couple the conductive coupling member 2120 with the second housing part 2110 when the electronic device 2100 is in the second state, thereby transmitting and receiving a signal by using a frequency band of 630 MHz to 750 MHz. The electronic device 2100 couples the conductive coupling member 2120 with the second housing part 2110 when the electronic device 2100 is in the second state, thereby transmitting and receiving a signal by using a frequency band of 660 MHz to 850 MHz. Therefore, the electronic device 2100 selectively couples the conductive coupling member 2120 with the second housing part 2110 by using the switching module 2140, thereby transmitting and receiving a signal by using a frequency band of 630 MHz to 850 MHz. In addition, the electronic device 2100 may couple the conductive coupling member 2120 with the second housing part 2110 by using the switching module 2140, thereby transmitting and receiving a signal with a high gain value.

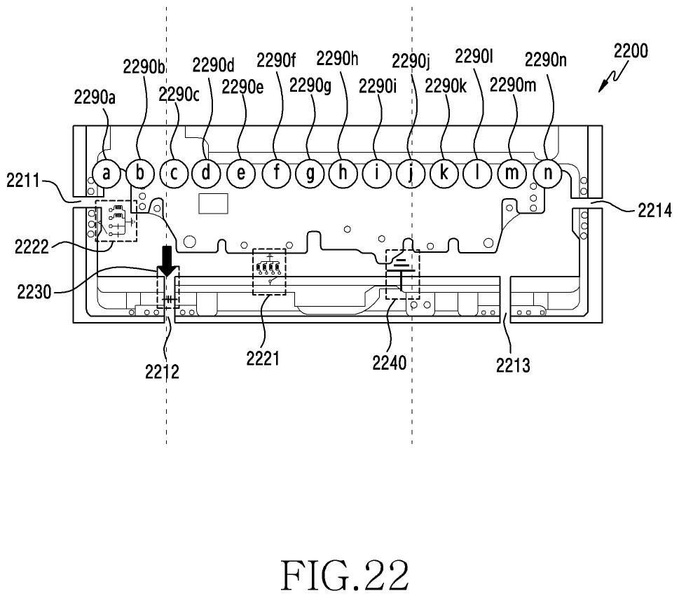

FIG. 22 is a drawing for explaining a second housing part with which a conductive coupling member of an electronic device is in contact according to an embodiment of the disclosure.

The electronic device of FIG. 22 and parts constituting the electronic device may correspond respectively to the electronic device 101 described above with reference to FIGS. 1, 2A to 2D, 3A, 3B, 4A, and 4B and parts constituting the electronic device 101. In addition, a second housing part 2200 of FIG. 22 may correspond to the second housing part 500 described above with reference to FIG. 5.

Referring to FIG. 22, a second housing part 2200 may include a conductive member serving as an antenna. For example, at least some of side members of the second housing part 2200 may include a conductive material. The electronic device may transmit and/or receive a signal wirelessly through the conductive member. The second housing part 2200 may include at least one of segments 2211, 2212, 2213, and 2214 to transmit and receive the signal. For example, first segment 2211 may be located at a side member disposed to one side of the second housing part 2200. For example, a fourth segment 2214 may be located at a side member disposed to the other side of the second housing part 2200. For example, a second segment 2212 and a third segment 2213 may be located at a side member disposed to a lower end of the second housing part 2200.

According to an embodiment, the conductive member of the second housing part 2200 may be power-fed through at least one point. For example, the electronic device may feed power to the conductive member through the second segment 2212 and/or a feeding portion 2230 disposed near the second segment 2212. For example, the electronic device may feed power to the feeding portion 2230 through a PCB mounted on the second housing part 2200. The power-fed conductive member of the second housing part 2200 may operate as an antenna.

According to an embodiment, a conductive member of the second housing part 2200 may be grounded through at least one point. For example, the conductive member may be grounded through at least one grounding portion 2240 disposed between the second segment 2212 and the third segment 2213.

According to an embodiment, the second housing part 2200 may be coupled with a flexible display through at least one point 2290a, 2290b, 2290c, 2290d, 2290e, 2290f, 2290g, 2290h, 2290i, 2290j, 2290k, 2290l, 2290m, or 2290n. The at least one point 2290a, 2290b, 2290c, 2290d, 2290e, 2290f, 2290g, 2290h, 2290i, 2290j, 2290k, 2290l, 2290m, or 2290n may be included in a region in which one end of the flexible display overlaps with the second housing part 2200 when the electronic device is in the second state. For example, the second housing part 2200 may be coupled to the flexible display through at least one point (e.g., 2290c, 2290d, 2290e, 2290f, 2290g, 2290h, 2290i, 2290j, 2290k, or 2290l) disposed to a center portion. For example, the second housing part 2200 may be coupled with the flexible display through at least one point (e.g., 2290c, 2290d, 2290e, 2290f, 2290g, 2290h, 2290i, or 2290j) corresponding to a region between the feeding portion 2230 and the grounding portion 2240. For example, the second housing part 2200 may be coupled with the flexible display through at least one point (e.g., 2290c, 2290d, 2290e, 2290f, 2290g, 2290h, 2290i, or 2290j) spaced apart from a first region between the feeding portion 2230 and the grounding portion 2240. For example, the second housing part 2200 may be coupled with the flexible display through at least one point (e.g., 2290c, 2290d, 2290e, 2290f, 2290g, 2290h, 2290i, or 2290j) included in a region in which one end of the flexible displays overlaps with the second housing part 2200 when the electronic device is in the second state, in a third region spaced in a lengthwise direction of the second housing part from the first region between the feeding portion 2230 and the grounding portion 2240.

According to an embodiment, the conductive member of the second housing part 2200 may be coupled with at least one element. For example, in the second housing part 2200, the second conductive member between the second segment 2212 and the third segment 2213 may be coupled with at least one element through a first switching module 2221. For example, the first switching module 2221 may be coupled to the first portion of the second conductive member between the feeding portion 2230 and the grounding portion 2240. For example, the first switching module 2221 may couple at least one element (e.g., an inductance element, a capacitance element), which changes a resonance frequency of the antenna, and the second conductive member. For example, the first switching module 2221 may couple an element (e.g., an inductance element, a capacitance element) for matching an impedance of the antenna to a specific impedance value and the second conductive member. For example, in the second housing part 2200, the first conductive member between the first segment 2211 and the second segment 2212 may be coupled to at least one element through a second switching module 2222. For example, the second switching module 2222 may be coupled to the first conductive member in the vicinity of the first segment 2211. For example, the second switching module 2222 may couple at least one element (e.g., an inductance element, a capacitance element), which changes a resonance frequency of the antenna, and the conductive member. For example, the second switching module 2222 may couple an element (e.g., an inductance element, a capacitance element) for matching an impedance of the antenna to a specific impedance value and the conductive member.

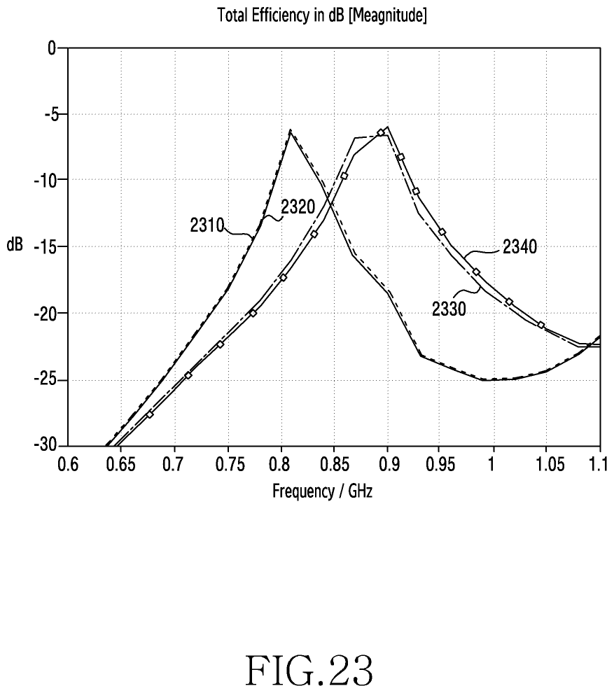

FIG. 23 is a drawing for explaining antenna performance depending on a position at which a conductive coupling member of an electronic device is in contact according to an embodiment of the disclosure.

Referring to FIG. 23, a first graph 2310 illustrates per-frequency efficiency of an antenna when a conductive coupling member is not in contact with a second housing part. Referring to the first graph 2310, the antenna may show high efficiency at a frequency band of about 810 MHz.

Referring to FIG. 23, a second graph 2320 illustrates per-frequency efficiency of an antenna when a conductive coupling member is in contact with a point ‘a’ (e.g., 2290a of FIG. 22) of a second housing part. Referring to the second graph 2320, the antenna may show high efficiency at a frequency band of about 810 MHz.

Referring to FIG. 23, a third graph 2330 illustrates per-frequency efficiency of an antenna when a conductive coupling member is in contact with a point ‘b’ (e.g., 2290b of FIG. 22) of a second housing part. Referring to the third graph 2330, the antenna may show high efficiency at a frequency band of about 860 MHz.

Referring to FIG. 23, a fourth graph 2340 illustrates per-frequency efficiency of an antenna when a conductive coupling member is in contact with a point ‘c’ (e.g., 2290c of FIG. 22) of a second housing part. Referring to the fourth graph 2340, the antenna may show high efficiency at a frequency band of about 900 MHz.

Referring to the first graph 2310 and the second graph 2320, the first graph 2310 and the second graph 2320 may be almost the same. When the conductive coupling member is in contact with a position near one side of the second housing part, there may be no effect in which the flexible display is grounded with the second housing part. Therefore, when the conductive coupling member is in contact with the position near the one side of the second housing part, antenna performance may not be guaranteed similarly to a case where the conductive coupling member is not in contact with the second housing part.

Referring to the first graph 2310 to the fourth graph 2340, the closer the conductive coupling member is coupled to a center portion of the second housing part, the higher band the resonance frequency of the antenna may move to. That is, the closer the conductive coupling member is coupled to the center portion of the second housing part, the lower the capacitance of the antenna, caused by coupling between the antenna and the flexible display, due to the effect in which the flexible display is grounded with the second housing part. Therefore, the conductive coupling member coupled to the flexible display may be in contact with the second housing part preferably at a place close to the center portion rather than near the side face of the second housing part.

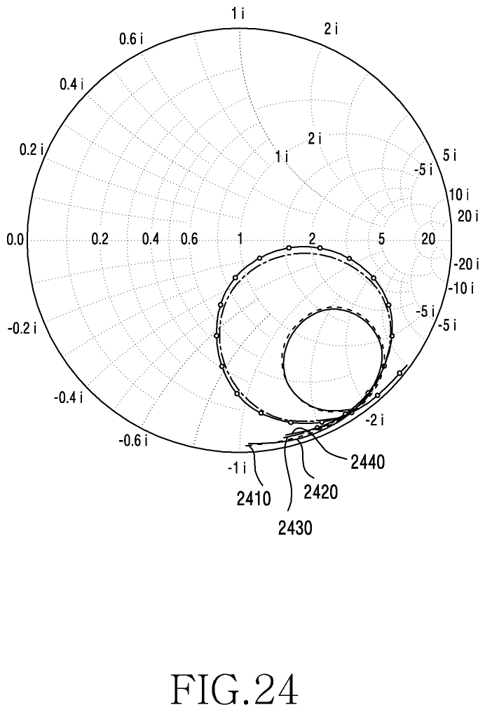

FIG. 24 is a drawing for explaining antenna performance depending on a position at which a conductive coupling member of an electronic device is in contact according to an embodiment of the disclosure.

FIG. 24 illustrates an impedance change depending on a position at which a conductive coupling member is in contact on a Smith chart drawn with a characteristic impedance of 50 Ohm. FIG. 24 may illustrate a characteristic impedance of an antenna, when the antenna is viewed at an electronic device. The antenna capacitance identified in FIG. 24 may be a capacitance component produced by coupling an antenna and a flexible display.

Referring to FIG. 24, a first graph 2410 illustrates a characteristic impedance of an antenna on a Smith chart when a conductive coupling member is not in contact with a second housing part. Referring to the first graph 2410, the antenna may have an impedance of about 1-1.1i.

Referring to FIG. 24, a second graph 2420 illustrates a characteristic impedance of an antenna on a Smith chart when a conductive coupling member is in contact with a point ‘a’ (e.g., 2290a of FIG. 22) of a second housing part. Referring to the second graph 2420, the antenna may have an impedance of about 1-1.1i.

Referring to FIG. 24, a third graph 2430 illustrates a characteristic impedance of an antenna on a Smith chart when a conductive coupling member is in contact with a point ‘b’ (e.g., 2290b of FIG. 22) of a second housing part. Referring to the third graph 2430, the antenna may have an impedance of about 1-0.38i.

Referring to FIG. 24, a fourth graph 2440 illustrates a characteristic impedance of an antenna on a Smith chart when a conductive coupling member is in contact with a point ‘c’ (e.g., 2290c of FIG. 22) of a second housing part. Referring to the fourth graph 2440, the antenna may have an impedance of about 1-0.3i.

Referring to the first graph 2410 and the second graph 2420, the first graph 2410 and the second graph 2420 may be almost the same. When the conductive coupling member is in contact at a position near one side of the second housing part, there may be capacitance caused by coupling between the antenna and the flexible display, similarly to a case where the conductive member is not in contact with the second housing part. That is, when the conductive coupling member is in contact with the position near the one side of the second housing part, there may be no effect in which the flexible display is grounded with the second housing part. Therefore, when the conductive coupling member is in contact with the position near the one side of the second housing part, antenna performance may not be guaranteed similarly to a case where the conductive coupling member is not in contact with the second housing part.

Referring to the first graph 2410 to the fourth graph 2440, the closer the conductive coupling member is coupled to a center portion of the second housing part, the higher band the resonance frequency of the antenna may move to. That is, the closer the conductive coupling member is coupled to the center portion of the second housing part, the lower the capacitance of the antenna, caused by coupling between the antenna and the flexible display, due to the effect in which the flexible display is grounded with the second housing part. Therefore, the conductive coupling member coupled to the flexible display may be in contact with the second housing part preferably at a place close to the center portion rather than near the side face of the second housing part.

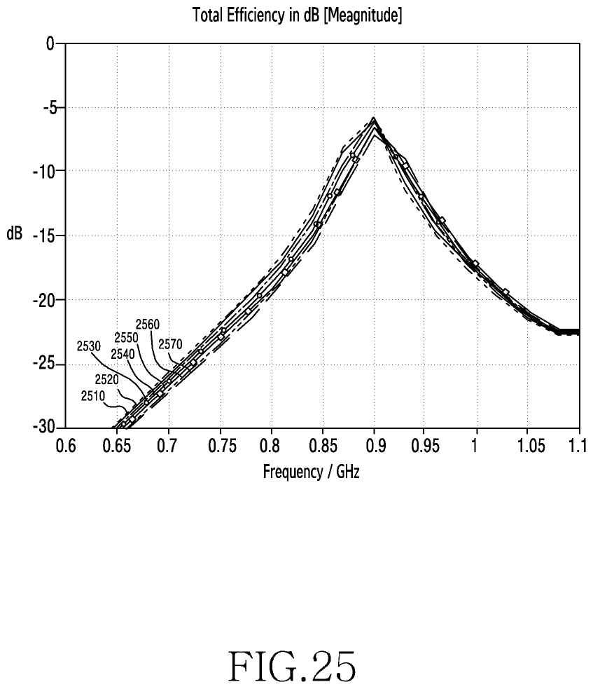

FIG. 25 is a drawing for explaining antenna performance depending on a position at which a conductive coupling member of an electronic device is in contact according to an embodiment of the disclosure.

Referring to FIG. 25, a first graph 2510 illustrates per-frequency efficiency of an antenna when a conductive coupling member is in contact with a point ‘c’ (e.g., 2290c of FIG. 22) of a second housing part. Referring to the first graph 2510, the antenna may show high efficiency at a frequency band of about 900 MHz.

Referring to FIG. 25, a second graph 2520 illustrates per-frequency efficiency of an antenna when a conductive coupling member is in contact with a point ‘d’ (e.g., 2290d of FIG. 22) of a second housing part. Referring to the second graph 2520, the antenna may show high efficiency at a frequency band of about 900 MHz.

Referring to FIG. 25, a third graph 2530 illustrates per-frequency efficiency of an antenna when a conductive coupling member is in contact with a point ‘e’ (e.g., 2290e of FIG. 22) of a second housing part. Referring to the third graph 2530, the antenna may show high efficiency at a frequency band of about 900 MHz.

Referring to FIG. 25, a fourth graph 2540 illustrates per-frequency efficiency of an antenna when a conductive coupling member is in contact with a point ‘f’ (e.g., 2290f of FIG. 22) of a second housing part. Referring to the fourth graph 2540, the antenna may show high efficiency at a frequency band of about 900 MHz.

Referring to FIG. 25, a fifth graph 2550 illustrates per-frequency efficiency of an antenna when a conductive coupling member is in contact with a point ‘g’ (e.g., 2290g of FIG. 22) of a second housing part. Referring to the fifth graph 2550, the antenna may show high efficiency at a frequency band of about 900 MHz.

Referring to FIG. 25, a sixth graph 2560 illustrates per-frequency efficiency of an antenna when a conductive coupling member is in contact with a point ‘h’ (e.g., 2290h of FIG. 22) of a second housing part. Referring to the sixth graph 2560, the antenna may show high efficiency at a frequency band of about 900 MHz.

Referring to FIG. 25, a seventh graph 2570 illustrates per-frequency efficiency of an antenna when a conductive coupling member is in contact with a point ‘i’ (e.g., 2290i of FIG. 22) of a second housing part. Referring to the seventh graph 2570, the antenna may show high efficiency at a frequency band of about 900 MHz.

Referring to FIG. 25, an eighth graph 2580 illustrates per-frequency efficiency of an antenna when a conductive coupling member is in contact with a point ‘j’ (e.g., 2290j of FIG. 22) of a second housing part. Referring to the eighth graph 2580, the antenna may show high efficiency at a frequency band of about 900 MHz.

Referring to the first graph 2510 to the eighth graph 2580, in all cases where a second housing part (e.g., 2200 of FIG. 22) is coupled with a flexible display through at least one point (e.g., 2290c, 2290d, 2290e, 2290f, 2290g, 2290h, 2290i, or 2290j) corresponding to a region between a feeding portion (e.g., 2230 of FIG. 22) and a grounding portion (e.g., 2240 of FIG. 22), an antenna may have high efficiency at a frequency band of about 900 MHz. That is, the second housing part (e.g., 2200 of FIG. 22) is coupled in a second region spaced apart from a first region between the flexible display and the feeding portion (e.g., 2230 of FIG. 22), and thus the second housing part (e.g., 2200 of FIG. 22) may be stably grounded with the flexible display.

Therefore, the conductive coupling member coupled to the flexible display may be preferably coupled to the second housing part (e.g., the second housing part 2200 of FIG. 22) through at least one point (e.g., 2290c, 2290d, 2290e, 2290f, 2290g, 2290h, 2290i, or 2290j of FIG. 22) included in a region in which one end of the flexible displays overlaps with the second housing part (e.g., 2200 of FIG. 22) when the electronic device is in the second state, in a third region spaced in a lengthwise direction of the second housing part from the first region between the feeding portion (e.g., 2230 of FIG. 22) and the grounding portion (e.g., 2240 of FIG. 22).

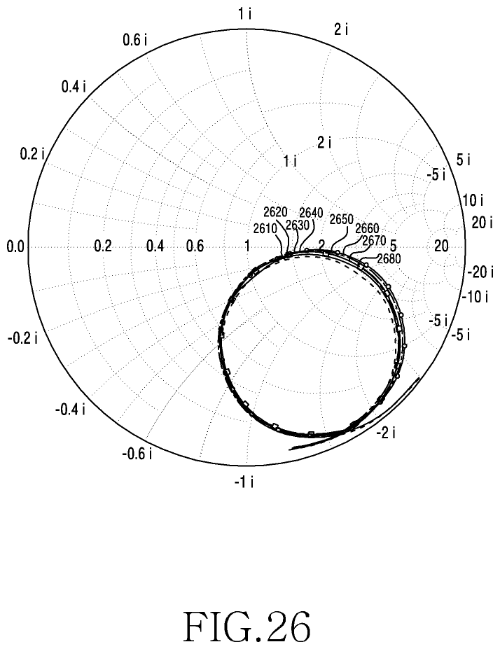

FIG. 26 is a drawing for explaining antenna performance depending on a position at which a conductive coupling member of an electronic device is in contact according to an embodiment of the disclosure.

FIG. 26 illustrates an impedance change depending on a position at which a conductive coupling member is in contact on a Smith chart drawn with a characteristic impedance of 50 Ohm. FIG. 26 may illustrate a characteristic impedance of an antenna, when the antenna is viewed at an electronic device. The antenna capacitance identified in FIG. 26 may be a capacitance component produced by coupling an antenna and a flexible display.

Referring to FIG. 26, a first graph 2610 illustrates a characteristic impedance of an antenna on a Smith chart when a conductive coupling member is in contact with a point ‘c’ (e.g., 2290c of FIG. 22) of a second housing part. Referring to the first graph 2610, the antenna may have an impedance of about 1-0.3i.

Referring to FIG. 26, a second graph 2620 illustrates a characteristic impedance of an antenna on a Smith chart when a conductive coupling member is in contact with a point ‘d’ (e.g., 2290d of FIG. 22) of a second housing part. Referring to the second graph 2620, the antenna may have an impedance of about 1-0.3i.

Referring to FIG. 26, a third graph 2630 illustrates a characteristic impedance of an antenna on a Smith chart when a conductive coupling member is in contact with a point ‘e’ (e.g., 2290e of FIG. 22) of a second housing part. Referring to the third graph 2630, the antenna may have an impedance of about 1-0.3i.

Referring to FIG. 26, a fourth graph 2640 illustrates a characteristic impedance of an antenna on a Smith chart when a conductive coupling member is in contact with a point ‘f’ (e.g., 2290f of FIG. 22) of a second housing part. Referring to the fourth graph 2640, the antenna may have an impedance of about 1-0.3i.

Referring to FIG. 26, a fifth graph 2650 illustrates a characteristic impedance of an antenna on a Smith chart when a conductive coupling member is in contact with a point ‘g’ (e.g., 2290g of FIG. 22) of a second housing part. Referring to the fifth graph 2650, the antenna may have an impedance of about 1-0.3i.

Referring to FIG. 26, a sixth graph 2660 illustrates a characteristic impedance of an antenna on a Smith chart when a conductive coupling member is in contact with a point ‘h’ (e.g., 2290h of FIG. 22) of a second housing part. Referring to the sixth graph 2660, the antenna may have an impedance of about 1-0.3i.

Referring to FIG. 26, a seventh graph 2670 illustrates a characteristic impedance of an antenna on a Smith chart when a conductive coupling member is in contact with a point ‘i’ (e.g., 2290i of FIG. 22) of a second housing part. Referring to the seventh graph 2670, the antenna may have an impedance of about 1-0.3i.

Referring to FIG. 26, an eighth graph 2680 illustrates a characteristic impedance of an antenna on a Smith chart when a conductive coupling member is in contact with a point ‘j’ (e.g., 2290j of FIG. 22) of a second housing part. Referring to the eighth graph 2680, the antenna may have an impedance of about 1-0.3i.

Referring to the first graph 2610 to the eighth graph 2680, in all cases in which a second housing part (e.g., 2200 of FIG. 22) is coupled with a flexible display through at least one point (e.g., 2290c, 2290d, 2290e, 2290f, 2290g, 2290h, 2290i, or 2290j of FIG. 22) corresponding to a region between a feeding portion (e.g., 2230 of FIG. 22) and a grounding portion (e.g., 2240 of FIG. 22), an antenna may have an impedance of about 1-0.3i. That is, the second housing part (e.g., 2200 of FIG. 22) is coupled in a second region spaced apart from a first region between the flexible display and the feeding portion (e.g., 2230 of FIG. 22), and thus the second housing part (e.g., 2200 of FIG. 22) may be stably grounded with the flexible display.

Therefore, the conductive coupling member coupled to the flexible display may be preferably coupled to the second housing part (e.g., the second housing part 2200 of FIG. 22) through at least one point (e.g., 2290c, 2290d, 2290e, 2290f, 2290g, 2290h, 2290i, or 2290j of FIG. 22) included in a region in which one end of the flexible displays overlaps with the second housing part (e.g., 2200 of FIG. 22) when the electronic device is in the second state, in a third region spaced in a lengthwise direction of the second housing part (e.g., 2200 of FIG. 22) from the first region between the feeding portion (e.g., 2230 of FIG. 22) and the grounding portion (e.g., 2240 of FIG. 22).

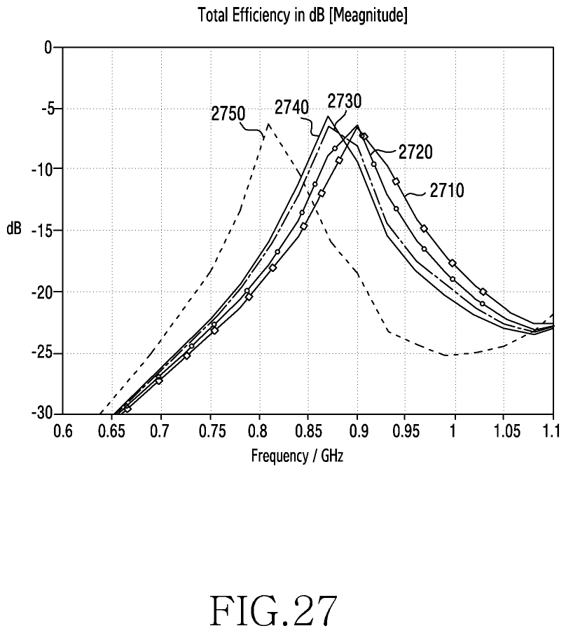

FIG. 27 is a drawing for explaining antenna performance depending on a position at which a conductive coupling member of an electronic device is in contact according to an embodiment of the disclosure.

Referring to FIG. 27, a first graph 2710 illustrates per-frequency efficiency of an antenna when a conductive coupling member is in contact with a point ‘j’ (e.g., 2290j of FIG. 22) of a second housing part. Referring to the first graph 2710, the antenna may show high efficiency at a frequency band of about 900 MHz.

Referring to FIG. 27, a second graph 2720 illustrates per-frequency efficiency of an antenna when a conductive coupling member is in contact with a point ‘k’ (e.g., 2290k of FIG. 22) of a second housing part. Referring to the second graph 2720, the antenna may show high efficiency at a frequency band of about 900 MHz.

Referring to FIG. 27, a third graph 2730 illustrates per-frequency efficiency of an antenna when a conductive coupling member is in contact with a point ‘l’ (e.g., 2290l of FIG. 22) of a second housing part. Referring to the third graph 2730, the antenna may show high efficiency at a frequency band of about 870 MHz.

Referring to FIG. 27, a fourth graph 2740 illustrates per-frequency efficiency of an antenna when a conductive coupling member is in contact with a point ‘m’ (e.g., 2290m of FIG. 22) of a second housing part. Referring to the fourth graph 2740, the antenna may show high efficiency at a frequency band of about 870 MHz.

Referring to FIG. 27, a fifth graph 2750 illustrates per-frequency efficiency of an antenna when a conductive coupling member is in contact with a point ‘n’ (e.g., 2290n of FIG. 22) of a second housing part. Referring to the fifth graph 2750, the antenna may show high efficiency at a frequency band of about 810 MHz.

Referring to the first graph 2710 to the fifth graph 2750, the closer the conductive coupling member is coupled to a center portion of the second housing part, the higher band the resonance frequency of the antenna may move to. The closer the conductive coupling member is coupled to the side face of the second housing part, the lower band the resonance frequency of the antenna may move to. That is, the closer the conductive coupling member is coupled to the center portion of the second housing part, the lower the capacitance of the antenna, caused by coupling between the antenna and the flexible display, due to the effect in which the flexible display is grounded with the second housing part. When the conductive coupling member is in contact with a position near one side of the second housing part, there may be no effect in which the flexible display is grounded with the second housing part. Therefore, the conductive coupling member coupled to the flexible display may be in contact with the second housing part preferably at a place close to the center portion rather than near the side face of the second housing part.

The conductive coupling member coupled to the flexible display may be preferably coupled to the second housing part (e.g., 2200 of FIG. 22) through a region between a first point, which is extended from the feeding portion (e.g., 2230 of FIG. 22) in a region in which one end of the flexible display overlaps with the second housing part (e.g., 2200 of FIG. 22) when the electronic device is in the second state, and a second point extended from the grounding portion (e.g., 2240 of FIG. 22) in a lengthwise direction of the second housing part (e.g., 2200 of FIG. 22).

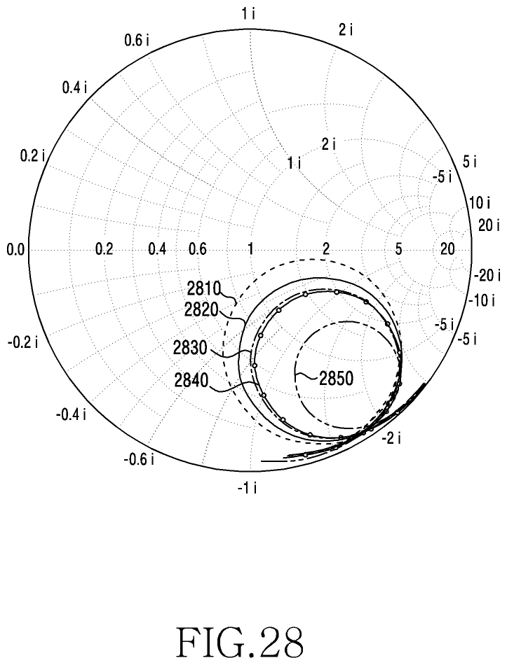

FIG. 28 is a drawing for explaining antenna performance depending on a position at which a conductive coupling member of an electronic device is in contact, according to an embodiment of the disclosure.

FIG. 28 illustrates an impedance change depending on a position at which a conductive coupling member is in contact on a Smith chart drawn with a characteristic impedance of 50 Ohm. FIG. 28 may illustrate a characteristic impedance of an antenna, when the antenna is viewed at an electronic device. The antenna capacitance identified in FIG. 28 may be a capacitance component produced by coupling an antenna and a flexible display.

Referring to FIG. 28, a first graph 2810 illustrates a characteristic impedance of an antenna on a Smith chart when a conductive coupling member is in contact with a point ‘j’ (e.g., 2290j of FIG. 22) of a second housing part. Referring to the first graph 2810, the antenna may have an impedance of about 1-0.3i.

Referring to FIG. 28, a second graph 2820 illustrates a characteristic impedance of an antenna on a Smith chart when a conductive coupling member is in contact with a point ‘k’ (e.g., 2290k of FIG. 22) of a second housing part. Referring to the second graph 2820, the antenna may have an impedance of about 1-0.5i.

Referring to FIG. 28, a third graph 2830 illustrates a characteristic impedance of an antenna on a Smith chart when a conductive coupling member is in contact with a point ‘l’ (e.g., 2290l of FIG. 22) of a second housing part. Referring to the third graph 2830, the antenna may have an impedance of about 1-0.61i.

Referring to FIG. 28, a fourth graph 2840 illustrates a characteristic impedance of an antenna on a Smith chart when a conductive coupling member is in contact with a point ‘m’ (e.g., 2290m of FIG. 22) of a second housing part. Referring to the fourth graph 2840, the antenna may have an impedance of about 1-0.65i.

Referring to FIG. 28, a fifth graph 2850 illustrates a characteristic impedance of an antenna on a Smith chart when a conductive coupling member is in contact with a point ‘n’ (e.g., 2290n of FIG. 22) of a second housing part. Referring to the fifth graph 2850, the antenna may have an impedance of about 1-1.2i.

Referring to the first graph 2810 to the fifth graph 2850, the closer the conductive coupling member is coupled to the center portion of the second housing part, the lower the antenna capacitance. The closer the conductive coupling member is coupled to the side face of the second housing part, the higher the antenna capacitance. That is, the closer the conductive coupling member is coupled to the center portion of the second housing part, the lower the antenna capacitance, caused by coupling between the antenna and the flexible display, due to an effect in which the flexible display is grounded with the second housing part. When the conductive coupling member is in contact at a position near one side of the second housing part, there may be no effect in which the flexible display is grounded with the second housing part. Therefore, the conductive coupling member coupled to the flexible display may be in contact with the second housing part preferably at a place close to the center portion rather than near the side face of the second housing part.

The conductive coupling member coupled to the flexible display may be preferably coupled to the second housing part (e.g., 2200 of FIG. 22) through a region between a first point, which is extended from the feeding portion (e.g., 2230 of FIG. 22) in a region in which one end of the flexible display overlaps with the second housing part (e.g., 2200 of FIG. 22) when the electronic device is in the second state, and a second point extended from the grounding portion (e.g., 2240 of FIG. 22) in a lengthwise direction of the second housing part (e.g., 2200 of FIG. 22).

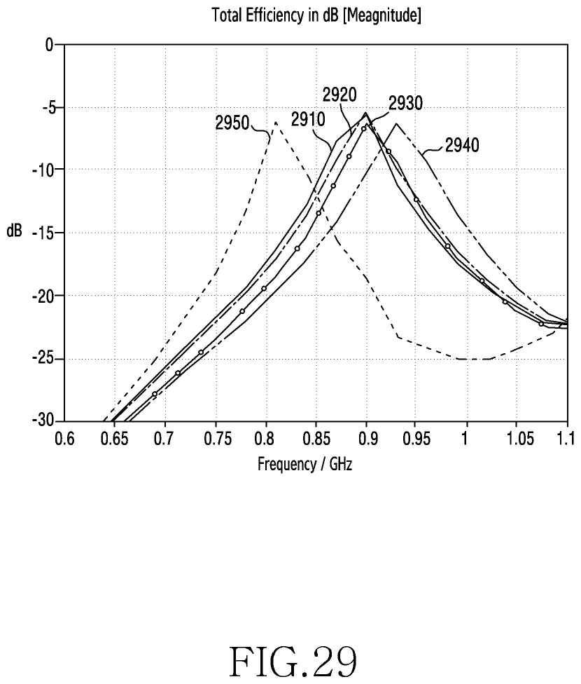

FIG. 29 is a drawing for explaining antenna performance depending on a position at which a conductive coupling member of an electronic device is in contact according to an embodiment of the disclosure.

Referring to FIG. 29, a first graph 2910 illustrates per-frequency efficiency of an antenna when a conductive coupling member is in contact with a point ‘c’ (e.g., 2290c of FIG. 22) of a second housing part. Referring to the first graph 2910, the antenna may show high efficiency at a frequency band of about 900 MHz.

Referring to FIG. 29, a second graph 2920 illustrates per-frequency efficiency of an antenna when a conductive coupling member is in contact with a plurality of points (e.g., 2290b, 2290c, and 2290d of FIG. 22) near a feeding portion (e.g., 2230 of FIG. 22) of a second housing part. Referring to the second graph 2920, the antenna may show high efficiency at a frequency band of about 900 MHz.

Referring to FIG. 29, a third graph 2930 illustrates per-frequency efficiency of an antenna when a conductive coupling member is in contact with a point (e.g., 2290j of FIG. 22) near a grounding portion (e.g., 2240 of FIG. 22) of a second housing part. Referring to the third graph 2930, the antenna may show high efficiency at a frequency band of about 900 MHz.

Referring to FIG. 29, a fourth graph 2940 illustrates per-frequency efficiency of an antenna when a conductive coupling member is in contact with all points 2290a, 2290b, 2290c, 2290d, 2290e, 2290f, 2290g, 2290h, 2290i, 2290j, 2290k, 2290l, 2290m, and 2290n corresponding to one end of a flexible display in a second housing part (e.g., 2200 of FIG. 22). Referring to the fourth graph 2940, the antenna may show high efficiency at a frequency band of about 930 MHz.

Referring to FIG. 29, a fifth graph 2950 illustrates per-frequency efficiency of an antenna when a conductive coupling member is not in contact with a second housing part. Referring to the fifth graph 2350, the antenna may show high efficiency at a frequency band of about 810 MHz.

Referring to the first graph 2910 to the fifth graph 2950, in the electronic device in the second state, a rear side of the second housing part is in contact with one end of the flexible display, and thus the resonance frequency of the antenna may be high-shifted. Since the rear side of the second housing part is in contact with the one end of the flexible display, unstable coupling between the second housing part and the flexible display becomes stable, and thus the resonance frequency of the antenna may be high-shifted.

The conductive coupling member is coupled with the second housing part (e.g., 2200 of FIG. 22) through at least one point (e.g., 2290c, 2290d, 2290e, 2290f, 2290g, 2290h, 2290i, or 2290j) corresponding to a first region between the feeding portion 2230 and the grounding portion 2240 in the second housing part (e.g., 2200 of FIG. 22), and thus a resonance frequency of an antenna may be high-shifted.

When the conductive coupling member is in contact at all points corresponding to one end of the flexible display in the second housing part (e.g., 2200 of FIG. 22), the resonance frequency of the antenna may be shifted to a higher band, compared to other cases. However, due to a constraint of an inner space of the electronic device, it may be difficult for the conductive coupling member to be in contact with all points corresponding to one end of the flexible display in the second housing part (e.g., 2200 of FIG. 22).

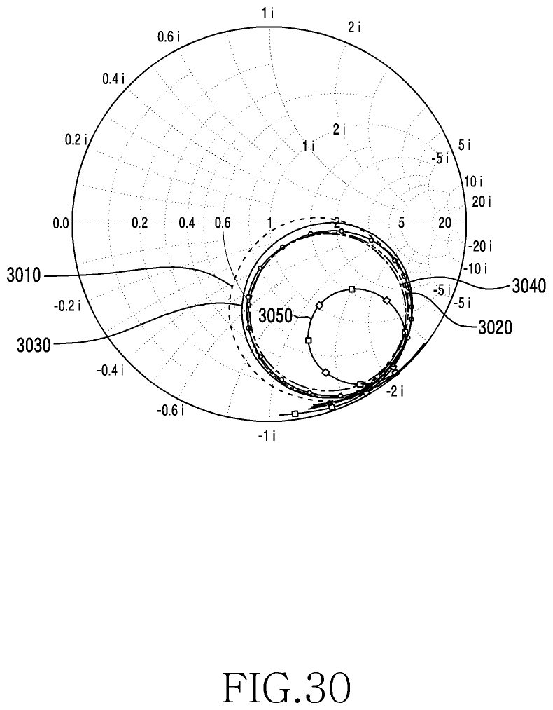

FIG. 30 is a drawing for explaining antenna performance depending on a position at which a conductive coupling member of an electronic device is in contact according to an embodiment of the disclosure.

FIG. 30 illustrates an impedance change depending on a position at which a conductive coupling member is in contact on a Smith chart drawn with a characteristic impedance of 50 Ohm. FIG. 30 may illustrate a characteristic impedance of an antenna, when the antenna is viewed at an electronic device. The antenna capacitance identified in FIG. 30 may be a capacitance component produced by coupling an antenna and a flexible display.

Referring to FIG. 30, a first graph 3010 illustrates a characteristic impedance of an antenna on a Smith chart when a conductive coupling member is in contact with all points 2290a, 2290b, 2290c, 2290d, 2290e, 2290f, 2290g, 2290h, 2290i, 2290j, 2290k, 2290l, 2290m, and 2290n corresponding to one end of a flexible display in a second housing part. Referring to the first graph 3010, the antenna may have an impedance of about 1-0.1i.

Referring to FIG. 30, a second graph 3020 illustrates a characteristic impedance of an antenna on a Smith chart when a conductive coupling member is in contact with a point ‘c’ (e.g., 2290c of FIG. 22) of a second housing part. Referring to the second graph 3020, the antenna may have an impedance of about 1-0.3i.

Referring to FIG. 30, a third graph 3030 illustrates a characteristic impedance of an antenna on a Smith chart when a conductive coupling member is in contact with a plurality of points (e.g., 2290b, 2290c, and 2290d of FIG. 22) near a feeding portion (e.g., 2230 of FIG. 22) of a second housing part. Referring to the third graph 3030, the antenna may have an impedance of about 1-0.2i.

Referring to FIG. 30, a fourth graph 3040 illustrates a characteristic impedance of an antenna on a Smith chart when a conductive coupling member is in contact with a point (e.g., 2290j of FIG. 22) near a grounding portion (e.g., 2240 of FIG. 22) of a second housing part. Referring to the fourth graph 3040, the antenna may have an impedance of about 1-0.3i.

Referring to FIG. 30, a fifth graph 3050 illustrates a characteristic impedance of an antenna on a Smith chart when a conductive coupling member is not in contact with a second housing part. Referring to the fifth graph 3050, the antenna may have an impedance of about 1-1.1i.

Referring to the first graph 2910 to the fifth graph 2950, a rear side of the second housing part and one end of the flexible display may be in contact in the electronic device in the second state, and thus a capacitance of an antenna may decrease, caused by coupling between the antenna and the flexible display due to the effect in which the flexible display is grounded with the flexible display. Since the rear side of the second housing part is in contact with the one end of the flexible display, unstable coupling between the second housing part and the flexible display becomes stable, thereby decreasing the capacitance of the antenna.

The conductive coupling member may be coupled with the second housing part (e.g., 2200 of FIG. 22) through at least one point (e.g., 2290c, 2290d, 2290e, 2290f, 2290g, 2290h, 2290i, or 2290j) corresponding to a first region between the feeding portion 2230 and the grounding portion 2240 in the second housing part (e.g., 2200 of FIG. 22), thereby decreasing the capacitance of the antenna.

The conductive coupling member is coupled with the second housing part (e.g., 2200 of FIG. 22) through a plurality of points (e.g., 2290b, 2290c, 2290d of FIG. 22), corresponding to the first region between the feeding portion 2230 and the grounding portion 2240, in the second housing part (e.g., 2200 of FIG. 22). Therefore, the capacitance of the antenna may be more decreased than a case of being coupled to the second housing part (e.g., 2200 of FIG. 22) through one point. When the conductive coupling member is in contact at all points corresponding to one end of the flexible display in the second housing part (e.g., 2200 of FIG. 22), the capacitance of the antenna may be more decreased than other cases.

Accordingly, the conductive coupling member may be in multi-point contact or surface contact with the second housing part (e.g., 2200 of FIG. 22) through at least one point (e.g., 2290c, 2290d, 2290e, 2290f, 2290g, 2290h, 2290i, or 2290j of FIG. 22) corresponding to a first region between the feeding portion 2230 and the grounding portion 2240.

An electronic device according to the disclosed embodiment may include a housing including a first housing part and a second housing part movably joined with the first housing part between a retracted position and an extended position with respect to the first housing part, a flexible display joined with the first housing part and the second housing part so that a region viewed to a front side of the housing changes in size with movement of the second housing part between the retracted position and the extended position, an actuator which moves the second housing part with respect to the first housing part, and a conductive coupling member which is disposed to one end of the flexible display and extends in a direction facing the second housing part. The flexible display may be rolled inside the second housing part toward a rear side of the second housing part. The one end of the flexible display may move in a lengthwise direction of the second housing part in the vicinity of the rear side of the second housing part, with the movement of the second housing part between the retracted position and the extended position with respect to the first housing part. When the second housing part moves from the retracted position to the extended position with respect to the first housing part, the conductive coupling member may be electrically coupled to the second housing part so that the flexible display is grounded to the second housing part.

According to an embodiment, the electronic device may further include a conductive member disposed at a lower end of the second housing part. When the second housing part moves from the retracted position to the extended position with respect to the first housing part, the flexible display may not be grounded to the second housing part, thereby changing a resonance frequency of the conductive member.

According to an embodiment, the flexible display may include a support member disposed at a rear side of the flexible display to support the flexible display. The conductive coupling member may be constructed by extending a portion of the support member disposed at the one end of the flexible display toward the rear side of the second housing part.

According to an embodiment, in the conductive coupling member, an end of the conductive coupling member disposed at the one end of the flexible display may be bent toward the rear side of the second housing part. A portion in a center of the conductive coupling member may be bent toward the flexible display such that the portion in the center of the conductive coupling member protrudes toward the rear side of the second housing part. The portion in the center of the conductive coupling member protruding toward the rear side of the second housing part may be in contact with the second housing part so that the flexible display is grounded to the second housing part.

According to an embodiment, the conductive coupling member may be an elastic body surrounded at least in part by a conductive material. The conductive material surrounding the elastic body may be in contact with the second housing part so that the flexible display is grounded to the second housing part.

According to an embodiment, the conductive coupling member may include a plate which extends toward the rear side of the second housing part to have a specific distance or less to the rear side of the second housing part, and which is disposed in parallel with the rear side of the second housing part. The plate may be electrically coupled to the rear side of the second housing part so that the flexible display is grounded to the second housing part.

According to an embodiment, the second housing part may include a contact portion constructed of a conductive material in a region corresponding to a position of the conductive coupling member when the second housing part moves to the extended position. The conductive coupling member may be in contact with the contact portion so that the flexible display is grounded to the second housing part.

According to an embodiment, the second housing part may include a recess extending from a first region corresponding to a position of the conductive coupling member when the second housing part moves to the retracted position to a second region corresponding to a position of the conductive coupling member when the second housing part moves to the extended position. The recess may be recessed to reduce a thickness of the second housing part from the first region to the second region so that the flexible display is not grounded to the second housing part, while the second housing part moves from the retracted position to the extended position with respect to the first housing part. The second region may include a contact portion constructed of a conductive material. The conductive coupling member may be constructed of the conductive material, and is in contact with the contact portion so that the flexible display is grounded to the second housing part.

According to an embodiment, the second housing part may include a slit extending from a first region corresponding to a position of the conductive coupling member when the second housing part moves to the retracted position to a position of a second region corresponding to a position of the conductive coupling member when the second housing part moves to the extended position. The second region may include a contact portion constructed of a conductive material. The conductive coupling member may be in contact with the contact portion so that the flexible display is grounded to the second housing part.

According to an embodiment, the slit may be internally filled with a non-conductive material so that the flexible display is not grounded to the second housing part, while the second housing part moves from the retracted position to the extended position with respect to the first housing part.

According to an embodiment, the conductive coupling member may be disposed to a center portion of the one end of the flexible display. The conductive coupling member may be electrically coupled to at least a portion of a rear side of the second housing part.

According to an embodiment, the electronic device may include a conductive member disposed to a lower end of the second housing part. The conductive member may be supplied with power through a first point and grounded through a second point. The conductive coupling member may be electrically coupled to at least a portion of a second region spaced apart from a first region between the first point and the second point.

According to an embodiment, the second region may be included in a region corresponding to one end of the flexible display at the rear side of the second housing part when the second hosing part moves to the extended position. The second region may be included in a region corresponding to a third region extending at the rear side of the second housing part in a lengthwise direction of the second housing part from a first region between the first point and the second point.

According to an embodiment, the electronic device may include a conductive member disposed to a lower end of the second housing part. The electronic device may include at least one element which changes a resonance frequency of the conductive member. The electronic device may include a switch which selectively couples the conductive member and the at least one element.

According to an embodiment, the second housing part may include a contact portion constructed of a conductive material in a region corresponding to a position of the conductive coupling member when the second housing part moves to the extended position. The electronic device may include a grounding portion to which the contact portion is grounded by being electrically coupled to the contact portion. The electronic device may include a switch which selectively couples the contact portion and the grounding portion.

Methods based on the embodiments disclosed in the claims and/or specification of the disclosure may be implemented in hardware, software, or a combination of both.

When implemented in software, a computer readable recording medium for storing one or more programs (i.e., software modules) may be provided. The one or more programs stored in the computer readable recording medium are configured for execution performed by one or more processors in the electronic device. The one or more programs include instructions for allowing the electronic device to execute the methods based on the embodiments disclosed in the claims and/or specification of the disclosure.

In the disclosure, a function or operation performed by an electronic device may be performed by at least one processor executing at least one instruction stored in memory. The function or operation of the electronic device mentioned in the disclosure may be performed by one processor executing at least one instruction, or may be performed by a combination of multiple processors executing one instruction. It may be understood that the processor mentioned in this disclosure includes a circuit for controlling other components of the electronic device. For example, the at least one processor may include a Central Processing Unit (CPU), a Micro-Processor Unit (MPU), an Application Processor (AP), a Communication Processor (CP), or a Neural Processing Unit (NPU), a System on Chip (SoC), or an Integrated Circuit (IC), which is configured to execute at least one instruction. The at least one processor may be configured to perform the operation of the electronic device described above.

In the disclosure, programs (e.g., software modules or software) may be stored in random access memory and/or non-volatile memory including flash memory, read only memory (ROM), an Electrically Erasable Programmable Read Only Memory (EEPROM), a magnetic disc storage device, a Compact Disc-ROM (CD-ROM), Digital Versatile Discs (DVDs), other forms of optical storage devices, or a magnetic cassette. Alternatively, the programs may be stored in memory configured in combination of all or some of these storage media. The memory may be constructed of a single storage medium or a combination of a plurality of storage media. The at least one instruction may be stored in the single storage medium, or may be stored in the plurality of storage media in a distributed manner.

Further, the program may be stored in an attachable storage device capable of accessing the electronic device through a communication network such as the Internet, an Intranet, a Local Area Network (LAN), a Wide LAN (WLAN), or a Storage Area Network (SAN) or a communication network configured by combining the networks. The storage device may have access to a device for performing an embodiment of the disclosure via an external port. In addition, an additional storage device on a communication network may have access to the device for performing the embodiment of the disclosure.

In the aforementioned specific embodiments of the disclosure, a component included in the disclosure is expressed in a singular or plural form according to the specific embodiment proposed herein. However, the singular or plural expression is selected properly for a situation proposed for the convenience of explanation, and thus the various embodiments of the disclosure are not limited to a single or a plurality of components. Therefore, a component expressed in a plural form may also be expressed in a singular form, or vice versa.

In addition, in the disclosure, the term “unit”, “module”, or the like may be a hardware component such as a processor or a circuit, and/or a software component executed by the hardware component such as the processor.

The “unit” and the “module” may be implemented by a program stored in an addressable storage medium and executable by the processor. For example, the “unit” and “module” may be implemented by software components, object-oriented software components, class components, and task components, processes, functions, attributes, procedures, subroutines, segments of program code, drivers, firmware, microcode, circuitry, data, databases, data structures, tables, arrays, and variables.

Specific implementations described in the disclosure are only one embodiment, and do not limit the scope of the disclosure in any way. For brevity of the specification, descriptions on the conventional electronic components, control systems, software, and other functional aspects of the systems may be omitted.

In addition, in the disclosure, “including at least one of a, b, or c” may mean “including only a”, “including only b”, “including only c”, “including a and b”, “including b and c”, “including a and c”, or “including a, b, and c”.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device individually or collectively, cause the electronic device to perform a method of the disclosure.

Any such software may be stored in the form of volatile or non-volatile storage such as, for example, a storage device like read only memory (ROM), whether erasable or rewritable or not, or in the form of memory such as, for example, random access memory (RAM), memory chips, device or integrated circuits or on an optically or magnetically readable medium such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a housing including a first housing part and a second housing part movably joined with the first housing part between a retracted position and an extended position with respect to the first housing part;
a flexible display joined with the first housing part and the second housing part so that a region viewed to a front side of the housing changes in size with movement of the second housing part between the retracted position and the extended position;
an actuator configured to move the second housing part with respect to the first housing part; and
a conductive coupling member disposed at one end of the flexible display and extending in a direction facing the second housing part,
wherein the flexible display is rolled inside the second housing part toward a rear side of the second housing part,
wherein the one end of the flexible display moves in a lengthwise direction of the second housing part in vicinity of the rear side of the second housing part with the movement of the second housing part between the retracted position and the extended position with respect to the first housing part, and
wherein, when the second housing part moves from the retracted position to the extended position with respect to the first housing part, the conductive coupling member is electrically coupled to the second housing part so that the flexible display is grounded to the second housing part.

2. The electronic device of claim 1, further comprising:
a conductive member disposed at a lower end of the second housing part,
wherein, when the second housing part moves from the retracted position to the extended position with respect to the first housing part, the flexible display is not grounded to the second housing part, thereby changing a resonance frequency of the conductive member.

3. The electronic device of claim 1,
wherein the flexible display includes a support member disposed at a rear side of the flexible display to support the flexible display, and
wherein the conductive coupling member is constructed by extending a portion of the support member disposed at the one end of the flexible display toward the rear side of the second housing part.

4. The electronic device of claim 1,
wherein, in the conductive coupling member, an end of the conductive coupling member disposed at the one end of the flexible display is bent toward the rear side of the second housing part,
wherein a portion in a center of the conductive coupling member is bent toward the flexible display such that the portion in the center of the conductive coupling member protrudes toward the rear side of the second housing part, and
wherein the portion in the center of the conductive coupling member protruding toward the rear side of the second housing part is in contact with the second housing part so that the flexible display is grounded to the second housing part.

5. The electronic device of claim 1,
wherein the conductive coupling member includes an elastic body surrounded at least in part by a conductive material, and
wherein the conductive material surrounding the elastic body is in contact with the second housing part so that the flexible display is grounded to the second housing part.

6. The electronic device of claim 1,
wherein the conductive coupling member includes a plate extending toward the rear side of the second housing part to have a specific distance or less to the rear side of the second housing part,
wherein the plate is disposed in parallel with the rear side of the second housing part, and
wherein the plate is electrically coupled to the rear side of the second housing part so that the flexible display is grounded to the second housing part.

7. The electronic device of claim 1,
wherein the second housing part includes a contact portion constructed of a conductive material in a region corresponding to a position of the conductive coupling member when the second housing part moves to the extended position, and
wherein the conductive coupling member is in contact with the contact portion so that the flexible display is grounded to the second housing part.

8. The electronic device of claim 1,
wherein the second housing part includes a recess extending from a first region corresponding to a position of the conductive coupling member when the second housing part moves to the retracted position to a second region corresponding to a position of the conductive coupling member when the second housing part moves to the extended position,
wherein the recess is recessed to reduce a thickness of the second housing part from the first region to the second region so that the flexible display is not grounded to the second housing part while the second housing part moves from the retracted position to the extended position with respect to the first housing part,
wherein the second region includes a contact portion constructed of a conductive material,
wherein the conductive coupling member is constructed of the conductive material, and
wherein the conductive coupling member is in contact with the contact portion so that the flexible display is grounded to the second housing part.

9. The electronic device of claim 1,
wherein the second housing part includes a slit extending from a first region corresponding to a position of the conductive coupling member when the second housing part moves to the retracted position to a position of a second region corresponding to a position of the conductive coupling member when the second housing part moves to the extended position,
wherein the second region includes a contact portion constructed of a conductive material, and
wherein the conductive coupling member is in contact with the contact portion so that the flexible display is grounded to the second housing part.

10. The electronic device of claim 9, wherein the slit is internally filled with a non-conductive material so that the flexible display is not grounded to the second housing part while the second housing part moves from the retracted position to the extended position with respect to the first housing part.

11. The electronic device of claim 1,
wherein the conductive coupling member is disposed to a center portion of the one end of the flexible display, and
wherein the conductive coupling member is electrically coupled to at least a portion of the rear side of the second housing part.

12. The electronic device of claim 11, further comprising:
a conductive member disposed to a lower end of the second housing part,
wherein the conductive member is supplied with power through a first point and grounded through a second point, and
wherein the conductive coupling member is electrically coupled to at least a portion of a second region spaced apart from a first region between the first point and the second point.

13. The electronic device of claim 12,
wherein the second region is included in a region corresponding to one end of the flexible display at the rear side of the second housing part when the second hosing part moves to the extended position, and
wherein the second region is included in a region corresponding to a third region extending at the rear side of the second housing part in a lengthwise direction of the second housing part from a first region between the first point and the second point.

14. The electronic device of claim 1, further comprising:
a conductive member disposed to a lower end of the second housing part;
at least one element changes a resonance frequency of the conductive member; and
a switch configured to selectively couple the conductive member and the at least one element.

15. The electronic device of claim 1,
wherein the second housing part includes a contact portion constructed of a conductive material in a region corresponding to a position of the conductive coupling member when the second housing part moves to the extended position, and
wherein the electronic device further comprises:
a grounding portion to which the contact portion is grounded by being electrically coupled to the contact portion; and
a switch configured to selectively couple the contact portion and the grounding portion.

16. The electronic device of claim 1,
wherein the conductive coupling member has no voltage difference or very slight voltage difference with respect to the flexible display, or may have a very slight difference, and
wherein the conductive coupling member is welded to the one end of the flexible display.

17. The electronic device of claim 1, wherein the conductive coupling member includes a c-clip constructed in a ‘C’ shape so that a portion in a center of the conductive coupling member is in contact with the rear side of the second housing part.

18. The electronic device of claim 1, further comprising:
a switch configured to selectively couple the conductive coupling member to the second housing part,
wherein the switch is configured to not couple the conductive coupling member with the second housing part when the electronic device is in the extended position, and
wherein the switch is configured to couple the conductive coupling member with the second housing part when the electronic device is in the retracted position.
